(19) United States
(12) Patent Application Publication
(10) Pub. No.: US 2024/0280731 A1
(43) Pub. Date: Aug. 22, 2024

(54) OPTICAL ELEMENT AND IMAGING DEVICE

(71) Applicant: HOYA CORPORATION, Tokyo (JP)

(72) Inventor: Shinichi OGAWA, Tokyo (JP)

(73) Assignee: HOYA CORPORATION, Tokyo (JP)

(21) Appl. No.: 18/633,885

(22) Filed: Apr. 12, 2024

Related U.S. Application Data
(63) Continuation of application No. PCT/JP2022/039953, filed on Oct. 26, 2022.

(30) Foreign Application Priority Data
Oct. 27, 2021 (JP) 2021-175681

(51) Int. Cl. G02B 1/14; C03C 3/247; C03C 4/08; G02B 1/11; G02B 5/28

(52) U.S. Cl. CPC G02B 1/14; C03C 3/247; C03C 4/082; C03C 4/085; G02B 1/11; G02B 5/281; G02B 5/283

(57) ABSTRACT

Provided is an optical element that can exhibit excellent weather resistance in spite of having a glass substrate formed of a phosphate glass or a fluorophosphate glass. The optical element is characterized by including a glass substrate formed of a phosphate glass or a fluorophosphate glass and a weather resistant protective film provided on at least one main surface and having a monolayer structure, wherein the weather resistant protective film contains one or more selected from Ti atoms, Zr atoms, and Al atoms together with Si atoms, and a proportion of the total number of Ti atoms, Zr atoms, and Al atoms in the total number of Si atoms, Ti atoms, Zr atoms, and Al atoms is more than 20.0 atomic % and 75.0 atomic % or less.

### CLAIM FOR PRIORITY

This application is a Continuation of PCT/JP2022/039953 filed Oct. 26, 2022, and claims the priority benefit of Japanese application 2021-175681 filed Oct. 27, 2021, the contents of which are expressly incorporated by reference herein in their entireties.

### TECHNICAL FIELD

The present disclosure relates to an optical element and an imaging device.

### BACKGROUND ART

In imaging devices having solid state imaging elements such as CCD and CMOS image sensors and installed in digital still cameras (DSCs) such as compact digital cameras and digital single lens reflex cameras, those called infrared cut filters (IRCFs), which transmit visible light and block ultraviolet light and near infrared light, are used to reproduce color tones well and obtain clear images (see, for example, Patent Literature 1 (Japanese Patent Laid-Open No. 2014-148567)).

FIG. 1 is a schematic illustration of a camera module constituting a DSC. FIG. 1(a) is a schematic illustration of a camera module pertaining to a compact digital camera installed in a smartphone or the like, and FIG. 1(b) is a schematic illustration of a camera module pertaining to a digital single lens reflex camera.

In the camera module shown in FIG. 1(a), an infrared cut filter (IRCF) 1 selectively reflects ultraviolet light and near infrared light of the light transmitted through a lens L to selectively introduce only light in the visible light region, which matches the human visual sensitivity characteristics, into the module and take it into an image sensor IC. Similarly, in the camera module shown in FIG. 1(b), an infrared cut filter (IRCF) 1 selectively reflects ultraviolet light and near infrared light of the light transmitted through a lens L, and a cover glass CG removes a rays and suppresses dust penetration, thereby selectively introducing only light in the visible light region, which matches the human visual sensitivity characteristics, into the module and taking it into an image sensor IC.

Then, as a constituent substrate for the above-described infrared cut filter (IRCF), an absorbing glass substrate that absorbs ultraviolet light or near infrared light is employed with an antireflection film (AR film) provided on the bottom side (light emitting side) of the glass substrate or with an absorbing resin film that absorbs ultraviolet light or near infrared light and an antireflection film (AR film) sequentially provided on the bottom side (light emitting side) of the glass substrate, whereby only light in the visible light region is transmitted in the bottom direction under high incident characteristics while effectively reducing ultraviolet light and near infrared light in the incident light.

### CITATION LIST

### Patent Literature

[Patent Literature 1] Japanese Patent Laid-Open No. 2014-148567

### SUMMARY OF INVENTION

### Technical Problem

However, the inventors of the present invention have conducted investigations and found that phosphate glasses, fluorophosphate glasses, etc. are normally used as constituent materials of the above-described absorbing glass substrate that absorbs ultraviolet light or near infrared light, and that such glasses are prone to glass weathering under high temperature and high humidity conditions, and the inventors have further found that when such glass weathering occurs, optical characteristics tend to be changed, and that the antireflection film, etc. provided on the surface of the glass substrate tend to be peeled off.

Under such circumstances, an object of the present disclosure is to provide an optical element that can exhibit excellent weather resistance in spite of having a glass substrate formed of a phosphate glass or a fluorophosphate glass, and to provide an imaging device comprising such an optical element.

### Solution to Problem

As a result of diligent investigations in order to achieve the above-described object, the inventors of the present invention have found that the above-described technical problem can be solved by an optical element comprising: a glass substrate formed of a phosphate glass or a fluorophosphate glass; and a weather resistant protective film provided on at least one main surface of the glass substrate and having a monolayer structure, wherein the weather resistant protective film contains one or more selected from Ti atoms, Zr atoms, and Al atoms together with Si atoms, and a proportion of the total number of Ti atoms, Zr atoms, and Al atoms in the total number of Si atoms, Ti atoms, Zr atoms, and Al atoms is more than 20.0 atomic % and 75.0 atomic % or less.

Specifically, the present disclosure is to provide the following:

(1) An optical element comprising: a glass substrate formed of a phosphate glass or a fluorophosphate glass; and a weather resistant protective film provided on at least one main surface of the glass substrate and having a monolayer structure,
wherein the weather resistant protective film contains one or more selected from Ti atoms, Zr atoms, and Al atoms together with Si atoms, and
a proportion of the total number of Ti atoms, Zr atoms, and Al atoms in the total number of Si atoms, Ti atoms, Zr atoms, and Al atoms is more than 20.0 atomic % and 75.0 atomic % or less.
   (2) The optical element according to the above (1), wherein Si atoms and one or more selected from Ti atoms, Zr atoms, and Al atoms, which constitute the weather resistant protective film, are bonded in a form of a three dimensional network by a chemical bond via an oxygen atom between homologous atoms or between heterologous atoms.
   (3) The optical element according to the above (1) or (2), wherein the weather resistant protective film contains 8.3 to 27.5 atomic % of Si atoms, 6.6 to 28.5 atomic % of one or more selected from Ti atoms, Zr atoms, and Al atoms, and 61.9 to 66.6 atomic % of oxygen atoms.
   (4) The optical element according to any of the above (1) to (3), wherein the weather resistant protective film contains a reaction product of
(I) one or more silicon compounds selected from alkoxysilanes, alkoxysilane derivatives, or oligomers as polymerization products of one or more thereof, with one or more multivalent metal compounds selected from
(IIa) alkoxytitaniums, alkoxytitanium derivatives, or oligomers as polymerization products of one or more thereof,
(IIb) alkoxyzirconiums, alkoxyzirconium derivatives, or oligomers as polymerization products of one or more thereof, and
(IIc) alkoxyaluminums, alkoxyaluminum derivatives, or oligomers as polymerization products of one or more thereof.
   (5) The optical element according to any of the above (1) to (4), comprising: the glass substrate formed of a phosphate glass or a fluorophosphate glass; and the weather resistant protective film provided on at least one main surface of the glass substrate, wherein the weather resistant protective film contains a hydrolysis and dehydration condensation product of an alkoxysilane represented by the following general formula (i):

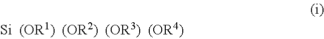

wherein R¹, R², R³, and R⁴ are linear or branched hydrocarbon groups having 1 to 10 carbon atoms, which may be identical or different from each other, with one or more selected from metal alkoxides each represented by
the following general formula (iia):

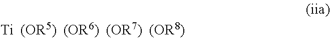

wherein R⁵, R⁶, R⁷, and R⁸ are linear or branched hydrocarbon groups having 1 to 10 carbon atoms, which may be identical or different from each other, the following general formula (iib):

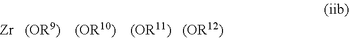

wherein R⁹, R¹⁰, R¹¹, and R¹² are linear or branched hydrocarbon groups having 1 to 10 carbon atoms, which may be identical or different from each other, and the following general formula (iic):

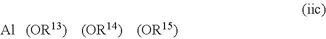

wherein R¹³, R¹⁴, and R¹⁵ are linear or branched hydrocarbon groups having 1 to 10 carbon atoms, which may be identical or different from each other.
   (6) The optical element according to the above (5), wherein, when a total content of the alkoxysilane represented by the general formula (i) and the one or more metal alkoxides selected from the general formula (iia) to the general formula (iic) is regarded as 100.0 mol %, the weather resistant protective film contains a hydrolysis and dehydration condensation product of
25.0 mol % or more and less than 80.0 mol % of the alkoxysilane represented by the general formula (i) with more than 20.0 mol % and 75.0 mol % or less of the one or more metal alkoxides selected from the general formula (iia) to the general formula (iic).
   (7) The optical element according to any of the above (1) to (6), wherein the glass substrate is an absorbing glass substrate that absorbs ultraviolet light or near infrared light.
   (8) The optical element according to any of the above (1) to (7), further comprising a resin film or an antireflection film on the weather resistant protective film.
   (9) The optical element according to any of the above (1) to (7), further comprising a resin film and an antireflection film in this order, or further comprising an antireflection film and a resin film in this order, on the weather resistant protective film.
   (10) The optical element according to any of the above (1) to (9), wherein the optical element is an optical filter.
   (11) An imaging device comprising the optical element according to any of the above (1) to (9) as an optical filter, together with a solid state imaging element and an imaging lens.

### Advantageous Effects of Invention

According to the present disclosure, there can be provided an optical element that can exhibit excellent weather resistance in spite of having a glass substrate formed of a phosphate glass or a fluorophosphate glass, and there can also be provided an imaging device comprising such an optical element.

### BRIEF DESCRIPTION OF DRAWINGS

FIGS. 1(a) and 1(b) are schematic illustrations of a camera module. FIG. 1(a) is a schematic illustration of a camera module pertaining to a compact digital camera, and FIG. 1(b) is a schematic illustration of a camera module pertaining to a digital single lens reflex camera.

FIG. 2 is a schematic illustration of an example of the form of the optical element according to the present disclosure.

FIG. 3 is a schematic illustration of an example of the form of the optical element according to the present disclosure.

### DESCRIPTION OF EMBODIMENTS

The optical element according to the present disclosure is characterized by comprising: a glass substrate formed of a phosphate glass or a fluorophosphate glass; and a weather resistant protective film provided on at least one main surface of the glass substrate and having a monolayer structure, wherein the weather resistant protective film contains one or more selected from Ti atoms, Zr atoms, and Al atoms together with Si atoms, and a proportion of the total number of Ti atoms, Zr atoms, and Al atoms in the total number of Si atoms, Ti atoms, Zr atoms, and Al atoms is more than 20.0 atomic % and 75.0 atomic % or less.

Hereinafter, the optical element according to the present disclosure will be described.

### [Glass Substrate]

The optical element according to the present disclosure comprises, as a glass substrate, a glass substrate formed of a phosphate glass or a fluorophosphate glass.

In the optical element according to the present disclosure, the thickness of the glass substrate is preferably 0.01 to 1.50 mm, more preferably 0.01 to 0.70 mm, and still more preferably 0.01 to 0.30 mm.

When the thickness of the glass substrate is within the above-described range, thinning of the optical element can be easily achieved.

In the optical element according to the present disclosure, the glass substrate is formed of a phosphate glass or a fluorophosphate glass.

The phosphate glass in the present disclosure is a glass that contains P and O as essential components and other optional components, and one that contains CuO is particularly preferable. When the phosphate glass contains CuO, it can absorb near infrared light more effectively. Examples of the other optional components in the phosphate glass include Ca, Mg, Sr, Ba, Li, Na, K, and Cs.

The fluorophosphate glass in the disclosure of the application is a glass that contains P, O, and F as essential components and other optional components, and one that contains CuO is particularly preferable. When the fluorophosphate glass contains CuO, it can absorb near infrared light more effectively. Examples of the other optional components in the fluorophosphate glass include Ca, Mg, Sr, Ba, Li, Na, K, and Cs.

The above-described phosphate glass is preferably one that contains:
more than 0% by mass and 70% by mass or less of P₂O₅;
0 to 40% by mass of Al₂O₃;
0 to 40% by mass of BaO; and
0 to 40% by mass of CuO.

The above-described phosphate glass is more preferably one that contains:
20 to 60% by mass of P₂O₅;
0 to 10% by mass of Al₂O₃;
0 to 10% by mass of BaO; and
0 to 10% by mass of CuO.

The above-described phosphate glass is still more preferably one that contains:
20 to 60% by mass of P₂O₅;
1 to 10% by mass of Al₂O₃;
1 to 10% by mass of BaO; and
1 to 10% by mass of CuO.

The above-described fluorophosphate glass is preferably one that contains:
more than 0% by mass and 70% by mass or less of P₂O₅;
0 to 40% by mass of Al₂O₃;
0 to 40% by mass of BaO; and
0 to 40% by mass of CuO,
and that further contains more than 0% by mass and 40% by mass or less of a fluoride.

The above-described fluorophosphate glass is more preferably one that contains:
20 to 60% by mass of P₂O₅;
0 to 10% by mass of Al₂O₃;
0 to 10% by mass of BaO; and
0 to 10% by mass of CuO,
and that further contains 1 to 30% by mass of a fluoride.

The above-described fluorophosphate glass is still more preferably one that contains:
20 to 60% by mass of P₂O₅;
1 to 10% by mass of Al₂O₃;
1 to 10% by mass of BaO; and
1 to 10% by mass of CuO,
and that further contains 2 to 30% by mass of a fluoride.

Examples of the above-described fluoride include one or more selected from MgF₂, CaF₂, SrF₂, etc.

In the optical element according to the present disclosure, the above-described glass substrate is preferably an absorbing glass substrate that absorbs ultraviolet light or near infrared light.

The absorbing glass substrate herein means a glass substrate used for absorbing only ultraviolet light, only near infrared light, or both ultraviolet light and near infrared light. Specifically, it means a glass that selectively absorbs only ultraviolet light (wavelength range of 200 to 400 nm), only near infrared light (wavelength range of 700 to 2500 nm), or both ultraviolet light and near infrared light, and selectively transmits light in the wavelength range of more than 400 nm and less than 700 nm, when irradiated with irradiation light including ultraviolet light (wavelength range of 200 to 400 nm) and visible light (wavelength range of more than 400 nm and 2500 nm or less).

The optical element according to the present disclosure is characterized by comprising, on at least one main surface of the above-described glass substrate, a weather resistant protective film having a monolayer structure.

Examples of the above-described weather resistant protective film may include those containing one or more selected from Ti atoms, Zr atoms, Al atoms, Mg atoms, P atoms, Ca atoms, Y atoms, Hf atoms, Nb atoms, Ta atoms, W atoms, Zn atoms, Ga atoms, In atoms, and La atoms together with Si atoms. Of these, one that contains one or more selected from Ti atoms, Zr atoms, and Al atoms together with Si atoms is employed in the optical element according to the present disclosure.

In the optical element according to the present disclosure, the weather resistant protective film may be one that contains one or more selected from Ti atoms, Zr atoms, and Al atoms together with Si atoms, and that further contains one or more selected from Mg atoms, P atoms, Ca atoms, Y atoms, Hf atoms, Nb atoms, Ta atoms, W atoms, Zn atoms, Ga atoms, In atoms, and La atoms.

In the optical element according to the present disclosure, examples of the weather resistant protective film may include those containing hydrolysis and dehydration condensation products of alkoxides of the respective metals, derivatives thereof, or oligomers as polymerization products of one or more thereof, as will be described later.

In the optical element according to the present disclosure, in the case where the weather resistant protective film is one that contains one or more selected from Ti atoms, Zr atoms, and Al atoms together with Si atoms, and that further contains one or more selected from Mg atoms, P atoms, Ca atoms, Y atoms, Hf atoms, Nb atoms, Ta atoms, W atoms, Zn atoms, Ga atoms, In atoms, and La atoms, the weather resistant protective film may be one that contains a hydrolysis and dehydration condensation product of a composite metal alkoxide containing multiple metals, such as yttrium aluminum-i-propoxide (Y [Al(O-i-C₃H₇)₄]₃).

In the optical element according to the present disclosure, the weather resistant protective film is one that has a monolayer structure containing one or more selected from Ti atoms, Zr atoms, and Al atoms together with Si atoms.

Herein, the monolayer structure means a layer structure characterized in that it is formed of a material having identical composition, on the basis of the measurement image (image contrast) or elemental analysis results obtained when measured with a scanning transmission electron microscope-energy dispersive X-ray spectrometer (STEM-EDX) under the following conditions.

### <Measurement Conditions>

Scanning transmission electron microscope: ARM200F manufactured by JEOL Ltd.

Energy dispersive X-ray spectrometer: JED-2300T manufactured by JEOL Ltd.

Sample preparation: focused ion beam (FIB) processing

Acceleration voltage: 200 kV

Elemental analysis: EDX mapping (resolution: 256×256)

In the optical element according to the present disclosure, the thickness of the weather resistant protective film is preferably 1000 nm or less, more preferably 10 to 500 nm, and still more preferably 30 to 300 nm.

When the thickness of the weather resistant protective film is 1000 nm or less, it is easier to suppress the occurrence of unevenness at the time of weather resistant protective film formation (at the time of heating), and the film surface of the weather resistant protective film can be easily made uniform.

Also, in the case where the thickness of the weather resistant protective film is 10 nm or more, it is easier for the weather resistant protective film to exhibit sufficient joining strength, and the mechanical strength of the optical element can be easily improved.

Herein, the thickness of the weather resistant protective film means the arithmetic mean value of 50 found values of the thickness of the weather resistant protective film in the measurement image (image contrast) of the cross section of the optical element obtained when measuring with the above-described STEM-EDX.

In the optical element according to the present disclosure, the weather resistant protective film contains one or more selected from Ti atoms, Zr atoms, and Al atoms together with Si atoms. As the one or more selected from Ti atoms, Zr atoms, and Al atoms contained in the weather resistant protective film together with Si atoms, Al atoms or Ti atoms are preferable, and Al atoms are more preferable.

In the weather resistant protective film constituting the optical element according to the present disclosure, the proportion of the total number of Ti atoms, Zr atoms, and Al atoms in the total number (total number of atoms) of Si atoms, Ti atoms, Zr atoms, and Al atoms, a (atomic %), is preferably more than 20.0 atomic % and 75.0 atomic % or less, more preferably 22.5 to 70.0 atomic %, and still more preferably 25.0 to 65.0 atomic %.

Herein, the above-described proportion of the total number of Ti atoms, Zr atoms, and Al atoms in the total number (total number of atoms) of Si atoms, Ti atoms, Zr atoms, and Al atoms constituting the weather resistant protective film, α(atomic %), means the value calculated by the following method.

(1) STEM-EDX measurement on the optical element is carried out according to the above-mentioned measurement conditions to obtain STEM-EDX lines (EDX ray (K ray) detection intensity lines in the depth direction of each element constituting the optical element).
(2) The EDX ray integrated intensity for Si atoms, XSi; the EDX ray integrated intensity for Ti atoms, XTi; the EDX ray integrated intensity for Zr atoms, XZr; and the EDX ray integrated intensity for Al atoms, XAl in the area constituting the weather resistant protective film are each determined.
(3) The value obtained by multiplying each EDX ray integrated intensity determined in (2) by the k factor (a correction factor that depends on, for example, the acceleration voltage and detection efficiency, and differs for each atomic number. Hereinafter, for the sake of convenience, the k factor for Si atoms is designated as KSi, the k factor for Ti atoms as KTi, the k factor for Zr atoms as KZr, and the k factor for Al atoms as KAl) can be regarded as corresponding to the weight ratio of each constituent element. Thus, for example, the weight proportion of Ti atoms constituting the weather resistant protective film, ATi (% by weight), can be calculated by the following expression.

$${A}_{Ti} = \frac{( {X}_{Ti} \times {K}_{T i} )}{( {X}_{S i} \times {K}_{S i} ) + ( {X}_{T i} \times {K}_{T i} ) + ( {X}_{Z r} \times {K}_{Z r} ) + ( {X}_{A 1} \times {K}_{A 1} )} \times 100 \qquad [ Expression 1 ]$$

(4) Furthermore, the value obtained by dividing, by each atomic weight M, the above-described value obtained by multiplying the EDX ray integrated intensity X of each atom by the k factor can be regarded as corresponding to the ratio of the number of atoms of each constituent element. Thus, in the case where the atomic weight of Si atoms is designated as MSi, the atomic weight of Ti atoms as MTi, the atomic weight of Zr atoms as MZr, and the atomic weight of Al atoms as MAl, for example, the proportion of the number of atoms of Ti atoms constituting the weather resistant protective film, aTi (atomic %), can be calculated by the following expression.

$${α}_{Ti} = \frac{( {X}_{T i} \times {K}_{T i} \div {M}_{T i} )}{( {X}_{Si} \times {K}_{Si} \div {M}_{Si} ) + ( {X}_{Ti} \times {K}_{Ti} \div {M}_{T i} ) + ( {X}_{Zr} \times {K}_{Zr} \div {M}_{Zr} ) + ( {X}_{A 1} \times {K}_{A 1} \div {M}_{A 1} )} \times 100 \qquad [ Expression 2 ]$$

Also, the proportion of the total number of atoms of Ti atoms, Zr atoms, and Al atoms constituting the weather resistant protective film, α(atomic %), can be calculated by the following expression.

$$α = \frac{( {X}_{T i} \times {K}_{Ti} \div {M}_{Ti} ) + ( {X}_{Z r} \times {K}_{Z r} \div {M}_{Zr} ) + ( {X}_{A 1} \times {A}_{A 1} \div {M}_{A 1} )}{( {X}_{Si} \times {K}_{Si} \div {M}_{Si} ) + ( {X}_{Ti} \times {K}_{T i} \div {M}_{Ti} ) + ( {X}_{Zr} \times {K}_{Zr} \div {M}_{Zr} ) + ( {X}_{A 1} \times {K}_{A 1} \div {M}_{A 1} )} \times 100 \qquad [ Expression 3 ]$$

For example, in the case where the weather resistant protective film contains Si atoms and Ti atoms but not Zr atoms and Al atoms, the proportion of the total number of atoms of Ti atoms, Zr atoms, and Al atoms constituting the weather resistant protective film, α(atomic %), can be calculated by the following expression.

$$α = \frac{( {X}_{T i} \times {K}_{Ti} \div {M}_{T i} )}{( {X}_{Si} \times {K}_{S i} \div {M}_{S i} ) + ( {X}_{T i} \times {K}_{T i} \div {M}_{T i} )} \times 100 \qquad [ Expression 4 ]$$

Note that, herein, K_{Si}=1.000, K_{Ti}=1.033, K_{Zr}=5.696, and K_{Al}=1.050.

In the optical element according to the present disclosure, the proportion of the total number of Si atoms, Ti atoms, Zr atoms, and Al atoms in the total number of metal atoms constituting the weather resistant protective film is preferably 70.0 to 100.0 atomic %, more preferably 80.0 to 100.0 atomic %, and still more preferably 90.0 to 100.0 atomic %.

Herein, the above-described proportion of the total number of atoms of Si atoms, Ti atoms, Zr atoms, and Al atoms in the total number of metal atoms constituting the weather resistant protective film (atomic %) also means the value calculated by the same method as for the above-described proportion of the total number of atoms of Ti atoms, Zr atoms, and Al atoms in the total number (total number of atoms) of Si atoms, Ti atoms, Zr atoms, and Al atoms constituting the weather resistant protective film, α(atomic %).

In the optical element according to the present disclosure, it is preferable that only one or more selected from Ti atoms, Zr atoms, and Al atoms should be contained, as the metal atoms constituting the weather resistant protective film, together with Si atoms.

In the optical element according to the present disclosure, Si atoms and one or more selected from Ti atoms, Zr atoms, and Al atoms, which constitute the weather resistant protective film, are preferably bonded in the form of a three dimensional network by a chemical bond via an oxygen atom between homologous atoms or between heterologous atoms.

Here, being bonded by a chemical bond via an oxygen atom between homologous atoms means that homologous atoms (Si atom and Si atom, Ti atom and Ti atom, Zr atom and Zr atom, or Al atom and Al atom) are bonded by a chemical bond via an oxygen atom. For example, in the case of Si atoms, it means that adjacent Si atoms form a chemical bond via an oxygen atom represented by —Si—O—Si—.

Also, being bonded by a chemical bond via an oxygen atom between heterologous atoms means that heterologous atoms (Si atom and Ti atom, Si atom and Zr atom, Si atom and Al atom, Ti atom and Zr atom, Ti atom and Al atom, or Zr atom and Al atom) are bonded by a chemical bond via an oxygen atom. For example, in the case where the above-described heterologous atoms are Si and Ti atoms, it means that adjacent Si and Ti atoms form a chemical bond via an oxygen atom represented by —Si—O—Ti—.

Si atoms and one or more selected from Ti atoms, Zr atoms, and Al atoms being bonded in the form of a three dimensional network by a chemical bond via an oxygen atom between homologous atoms or between heterologous atoms means that innumerable metal atoms are bonded in the form of a network in the three dimensional direction while adjacent metal atoms form a chemical bond via an oxygen atom.

In the optical element according to the present disclosure, examples of the weather resistant protective film may include those containing hydrolysis and dehydration condensation products of alkoxides of the respective metals, derivatives thereof, or oligomers as polymerization products of one or more thereof, as will be described later, and such hydrolysis and dehydration condensation products can easily form the above-described structure in which Si atoms and one or more selected from Ti atoms, Zr atoms, and Al atoms are bonded in the form of a three dimensional network by a chemical bond via an oxygen atom between homologous atoms or between heterologous atoms.

In the optical element according to the present disclosure, Si atoms and one or more selected from Ti atoms, Zr atoms, and Al atoms, which constitute the weather resistant protective film, being bonded in the form of a three dimensional network by a chemical bond via an oxygen atom between homologous atoms or between heterologous atoms can be confirmed by vibrational spectroscopy (infrared spectroscopy, Raman spectroscopy).

In the optical element according to the present disclosure, the weather resistant protective film contains Si atoms and one or more selected from Ti atoms, Zr atoms and Al atoms as essential components.

In the optical element according to the present disclosure, in the case where the weather resistant protective film is in a state where multiple atoms are bonded three dimensionally by a chemical bond via an oxygen atom between homologous atoms or between heterologous atoms, the weather resistant protective film is preferably one that contains 8.3 to 27.5 atomic %, more preferably one that contains 13.3 to 26.8 atomic %, and still more preferably one that contains 16.6 to 26.0 atomic % of Si atoms.

In the optical element according to the present disclosure, the weather resistant protective film is preferably one that contains 6.6 to 28.5 atomic %, more preferably one that contains 7.5 to 22.2 atomic %, and still more preferably one that contains 8.3 to 18.1 atomic % of one or more selected from Ti atoms, Zr atoms, and Al atoms.

In the optical element according to the present disclosure, the weather resistant protective film is preferably one that contains 61.9 to 66.6 atomic %, more preferably one that contains 62.9 to 66.6 atomic %, and still more preferably one that contains 63.6 to 66.6 atomic % of oxygen atoms.

Herein, the content of Si atoms and the content of one or more selected from Ti atoms, Zr atoms, and Al atoms, which constitute the weather resistant protective film, mean the values measured by ICP (inductively coupled plasma) spectroscopic analysis.

Also, herein, the content of oxygen atoms constituting the weather resistant protective film means the value measured by the inorganic element analysis method.

In the optical element according to the present disclosure, the weather resistant protective film is preferably one that contains a hydrolysis and dehydration condensation product of

(I) alkoxysilanes, alkoxysilane derivatives, or oligomers as polymerization products of one or more thereof, with one or more selected from
(IIa) alkoxytitaniums, alkoxytitanium derivatives, or oligomers as polymerization products of one or more thereof,
(IIb) alkoxyaluminums, alkoxyaluminum derivatives, or oligomers as polymerization products of one or more thereof, and
(IIc) alkoxyaluminums, alkoxyaluminum derivatives, or oligomers as polymerization products of one or more thereof.

Examples of the above-described alkoxysilanes used as starting materials for the weather resistant protective film may include one or more selected from tetramethyl silicate, tetraethyl silicate, tetrapropyl silicate, and tetrabutyl silicate, and in consideration of reactivity, one or more selected from tetramethyl silicate and tetraethyl silicate are preferable.

The above-described alkoxysilane derivatives used as starting materials for the weather resistant protective film are compounds derived from alkoxysilanes and having functional groups other than alkoxy groups introduced as some or all of the substituents, and are preferably those having functional groups that can react with hydroxyl groups on the surface of the glass substrate, alkoxysilane derivatives, and other constituent components constituting the weather resistant protective film to form bonds at the time of hydrolysis and dehydration condensation reaction. Specific examples thereof may include the following.

### (Those Having Alkyl Group as Functional Group)

Methyltrimethoxysilane, methyltriethoxysilane, dimethyldiethoxysilane, trimethylmethoxysilane, n-propyltriethoxysilane, n-hexyltriethoxysilane, etc.

### (Those Having Aromatic Group (Phenyl Group) as Functional Group)

Phenyltrimethoxysilane, phenyltriethoxysilane, etc.

### (Those Having Vinyl Group as Functional Group)

Vinyltrimethoxysilane, vinyltriethoxysilane, etc.

### (Those Having Epoxy Group as Functional Group)

3-Glycidoxypropyltriethoxysilane, 3-glycidoxypropylmethyldimethoxysilane, 2-(3,4-epoxycyclohexyl)ethyltrimethoxysilane, etc.

### (Those Having Styryl Group as Functional Group)

p-Styryltrimethoxysilane, etc.

### (Those Having Methacryl Group as Functional Group)

3-Methacryloxypropyltriethoxysilane, 3-methacryloxypropylmethyldimethoxysilane, etc.

(Those in which Functional Group is Acryl Group)

3-Acryloxypropyltrimethoxysilane, etc.

### (Those Having Amino Group as Functional Group)

3-Aminopropyltriethoxysilane, N-2-(aminoethyl)-3-aminopropylmethyldimethoxysilane, 3-triethoxysilyl-N-(1,3-dimethyl-butylidene)propylamine, N-phenyl-3-aminopropyltrimethoxysilane, etc.

### (Those Having Ureide Group as Functional Group)

Tris-(trimethoxysilylpropyl) isocyanurate, etc.

### (Those Having Mercapto Group as Functional Group)

3-Mercaptopropyltrimethoxysilane, 3-mercaptopropylmethyldimethoxysilane, etc.

### (Those Having Isocyanate Group as Functional Group)

3-isocyanatopropyltriethoxysilane, tetraisocyanatosilane, monomethyltriisocyanatosilane, etc.

### (Those Having Halogen as Functional Group)

Silicon tetrachloride, etc.

Examples of the above-described oligomers as polymerization products of one or more selected from alkoxysilanes and alkoxysilane derivatives used as starting materials for the weather resistant protective film may include oligomers as polymerization products of monomers formed of any one or more of the above-mentioned alkoxysilanes, oligomers as polymerization products of monomers formed of any one or more of the above-mentioned alkoxysilane derivatives, and oligomers as polymerization products of monomers formed of any one or more of the above-mentioned alkoxysilanes and monomers formed of any one or more of the above-mentioned alkoxysilane derivatives.

Examples of the above-described alkoxytitaniums used as starting materials for the weather resistant protective film may include one or more selected from titanium(IV) tetramethoxide, titanium(IV) tetraethoxide, titanium(IV) tetra-iso-propoxide, titanium(IV) tetra-n-butoxide, etc.

The above-described alkoxytitanium derivatives used as starting materials for the weather resistant protective film are compounds derived from alkoxytitaniums and having functional groups other than alkoxy groups introduced as some or all of the substituents, and are preferably those having functional groups that can react with hydroxyl groups on the surface of the glass substrate, alkoxytitanium derivatives, and other constituent components constituting the weather resistant protective film to form bonds at the time of hydrolysis and dehydration condensation reaction.

Specific examples of the alkoxytitanium derivatives may include one or more selected from titanium diisopropoxy bis(acetylacetonate), titanium diisopropoxy bis(ethylacetoacetate), titanium octylene glycolate, titanium tetraacetylacetonate, titanium diisopropoxy bis(triethanolaminate), titanyl chloride, titanium tetrachloride, etc.

Examples of the above-described oligomers as polymerization products of one or more selected from alkoxytitaniums and alkoxytitanium derivatives used as starting materials for the weather resistant protective film may include oligomers as polymerization products of monomers formed of any one or more of the above-mentioned alkoxytitaniums, oligomers as polymerization products of monomers formed of any one or more of the above-mentioned alkoxytitanium derivatives, and oligomers as polymerization products of monomers formed of any one or more of the above-mentioned alkoxytitaniums and monomers formed of any one or more of the above-mentioned alkoxytitanium derivatives.

Examples of the above-described alkoxyzirconiums used as starting materials for the weather resistant protective film may include one or more selected from zirconium(IV) tetramethoxide, zirconium(IV) tetraethoxide, zirconium(IV) tetra-n-propoxide, zirconium(IV) tetra-i-propoxide, zirconium(IV) tetra-n-butoxide, etc.

The above-described alkoxyzirconium derivatives used as starting materials for the weather resistant protective film are compounds derived from alkoxyzirconiums and having functional groups other than alkoxy groups introduced as some or all of the substituents, and are preferably those having functional groups that can react with hydroxyl groups on the surface of the glass substrate, alkoxyzirconium derivatives, and other constituent components constituting the weather resistant protective film to form bonds at the time of hydrolysis and dehydration condensation reaction.

Specific examples of the alkoxyzirconium derivatives may include one or more selected from zirconium tributoxy monoacetylacetonate, zirconium dibutoxy bis(ethylacetoacetate), (isopropoxy)tris(dipivaloylmethanato)zirconium, etc.

Examples of the above-described oligomers as polymerization products of one or more selected from alkoxyzirconiums and alkoxyzirconium derivatives used as starting materials for the weather resistant protective film may include oligomers as polymerization products of monomers formed of any one or more of the above-mentioned alkoxyzirconiums, oligomers as polymerization products of monomers formed of any one or more of the above-mentioned alkoxyzirconium derivatives, and oligomers as polymerization products of monomers formed of any one or more of the above-mentioned alkoxyzirconiums and monomers formed of any one or more of the above-mentioned alkoxyzirconium derivatives.

Examples of the above-described alkoxyaluminums used as starting materials for the weather resistant protective film may include one or more selected from aluminum(III) trimethoxide, aluminum(III) triethoxide, aluminum(III) tri-n-propoxide, aluminum tri-i-propoxide, aluminum(III) tri-sec-butoxide, aluminum(III) di-i-propylate mono-sec-butyrate, etc.

The above-described alkoxyaluminum derivatives used as starting materials for the weather resistant protective film are compounds derived from alkoxyaluminums and having functional groups other than alkoxy groups introduced as some or all of the substituents, and are preferably those having functional groups that can react with hydroxyl groups on the surface of the glass substrate, alkoxyaluminum derivatives, and other constituent components constituting the weather resistant protective film to form bonds at the time of hydrolysis and dehydration condensation reaction.

Specific examples of the alkoxyaluminum derivatives may include one or more selected from aluminium ethylacetoacetate diisopropylate, aluminium alkylacetoacetate diisopropylate, aluminum tris(acetylacetonate), aluminum tris(ethylacetoacetate), aluminum monoacetylacetonate bis(ethylacetoacetate), cyclic aluminum oxide stearate, cyclic aluminum oxide octylate, etc.

Examples of the above-described oligomers as polymerization products of one or more selected from alkoxyaluminums and alkoxyaluminum derivatives used as starting materials for the weather resistant protective film may include oligomers as polymerization products of monomers formed of any one or more of the above-mentioned alkoxyaluminums, oligomers as polymerization products of monomers formed of any one or more of the above-mentioned alkoxyaluminum derivatives, and oligomers as polymerization products of monomers formed of any one or more of the above-mentioned alkoxyaluminums and monomers formed of any one or more of the above-mentioned alkoxyaluminum derivatives.

In the optical element according to the present disclosure, when the total content of the above-described (I) silicon compounds and the above-described one or more multivalent metal compounds selected from (IIa) through (IIc) is regarded as 100.0 mol %, the weather resistant protective film is preferably a reaction product of 25.0 mol % or more and less than 80.0 mol % of the above-described (I) silicon compounds with more than 20.0 mol % and 75.0 mol % or less of the above-described one or more metal alkoxides selected from the general formula (IIa) to the general formula (IIc), more preferably a reaction product of 30.0 mol % to 77.5 mol % of the above-described (I) silicon compounds with 22.5 mol % to 70.0 mol % of the above-described one or more metal alkoxides selected from the general formula (IIa) to the general formula (IIc), and still more preferably a reaction product of 35.0 mol % to 75.0 mol % of the above-described (I) silicon compounds with 25.0 mol % to 65.0 mol % of the above-described one or more metal alkoxides selected from the general formula (IIa) to the general formula (IIc).

More specific examples of the optical element according to the present disclosure may include those comprising: a glass substrate formed of a phosphate glass or a fluorophosphate glass; and a weather resistant protective film provided on at least one main surface of the glass substrate, wherein the weather resistant protective film contains a hydrolysis and dehydration condensation product of an alkoxysilane represented by the following general formula (i):

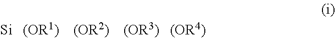

wherein R¹, R², R³, and R⁴ are linear or branched hydrocarbon groups having 1 to 10 carbon atoms, which may be identical or different from each other, with one or more selected from metal alkoxides each represented by
the following general formula (iia):

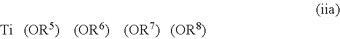

wherein R⁵, R⁶, R⁷, and R⁸ are linear or branched hydrocarbon groups having 1 to 10 carbon atoms, which may be identical or different from each other, the following general formula (iib):

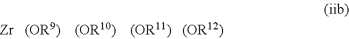

wherein R⁹, R¹⁰, R¹¹, and R¹² are linear or branched hydrocarbon groups having 1 to 10 carbon atoms, which may be identical or different from each other, and
the following general formula (iic):

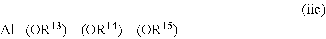

wherein R¹³, R¹⁴, and R¹⁵ are linear or branched hydrocarbon groups having 1 to 10 carbon atoms, which may be identical or different from each other.

In the compound represented by the general formula (i),

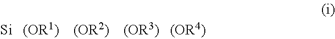

R¹, R², R³, and R⁴ are linear or branched hydrocarbon groups having 1 to 10 carbon atoms, preferably linear or branched hydrocarbon groups having 1 to 4 carbon atoms, and more preferably linear or branched hydrocarbon groups having 1 to 3 carbon atoms.

Specific examples of R¹, R², R³, and R⁴ may include those selected from linear, branched, and cyclic hydrocarbon groups such as methyl group, ethyl group, propyl group, butyl group, pentyl group, hexyl group, heptyl group, octyl group, nonyl group, and decyl group, etc.

R¹, R², R³, and R⁴ may be identical or different from each other.

In the optical element according to the present disclosure, when the number of carbon atoms in R¹, R², R³, and R⁴ is within the above-described range, it is easier to maintain a suitable reaction rate between the alkoxysilane and the metal alkoxides, and it is easier to carry out a more homogeneous reaction.

In the above-described titanium alkoxide represented by the general formula (iia) Ti(OR⁵) (OR⁶) (OR⁷) (OR^{B}), the above-described zirconium alkoxide represented by the general formula (iib) Zr (OR⁹) (OR¹⁰) (OR¹¹) (OR¹²), and the above-described aluminum alkoxide represented by the general formula (iic) Al (OR¹³) (OR¹⁴) (OR¹⁵), R⁵ to R¹⁵ (R⁵, R⁶, R⁷, R⁰, R⁹, R¹⁰, R¹¹, R¹², R¹³, R¹⁴, and R¹⁵) are linear or branched hydrocarbon groups having 1 to 10 carbon atoms, preferably linear or branched hydrocarbon groups having 2 to 9 carbon atoms, and more preferably linear or branched hydrocarbon groups having 3 to 8 carbon atoms.

Specific examples of R⁵, R⁶, R⁷, R⁸, R⁹, R¹⁰, R¹¹, R¹², R¹³, R¹⁴, or R¹⁵ may include those selected from linear, branched, and cyclic hydrocarbon groups such as methyl group, ethyl group, propyl group, butyl group, pentyl group, hexyl group, heptyl group, octyl group, nonyl group, and decyl group, etc.

R⁵, R⁶, R⁷, R⁸, R⁹, R¹⁰, R¹¹, R¹², R¹³, R¹⁴, and R¹⁵ may be identical or different from each other.

In the optical element according to the present disclosure, when the number of carbon atoms in R⁵, R⁶, R⁷, R⁸, R⁹, R¹⁰, R¹¹, R¹², R¹³, R¹⁴, and R¹⁵ is 2 or more, the stability of the metal alkoxides against moisture can be effectively improved, and when it is 9 or less, an increase in viscosity of the metal alkoxides can be suppressed and handleability can be effectively enhanced.

The alkoxysilane represented by the general formula (i) can be hydrolyzed, thereby easily producing a compound having reactive silanol groups (Si—OH groups).

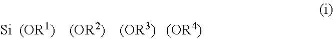

In the case where the above-described alkoxysilane represented by the general formula (i) is partially hydrolyzed, the reaction proceeds as follows, for example.

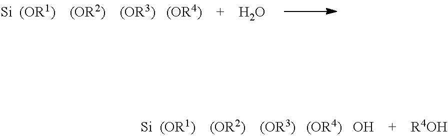

Also, in the case where all alkoxy groups in the above-described alkoxysilane represented by the general formula (i) are hydrolyzed, the reaction proceeds as follows to produce a silanol Si (OH)₄.

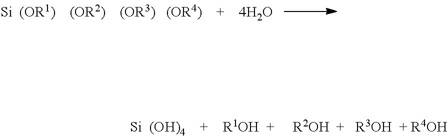

The above-described titanium alkoxide represented by the general formula (iia) Ti(OR⁵) (OR⁶) (OR¹¹) (OR⁸), the above-described zirconium alkoxide represented by the general formula (iib) Zr (OR⁹) (OR¹⁰) (OR¹¹) (OR¹²), and the above-described aluminum alkoxide represented by the general formula (iic) Al (OR¹³) (OR¹⁴) (OR¹⁵) are also hydrolyzed, thereby easily producing compounds having a hydroxyl group in the same manner.

Then, by allowing the hydrolyzed product of the above-described alkoxysilane represented by the general formula (i) to undergo a dehydration condensation reaction with the hydrolyzed products of one or more metal alkoxides selected from the above-described titanium alkoxide represented by the general formula (iia), the above-described zirconium alkoxide represented by the general formula (iib), and the above-described aluminum alkoxide represented by the general formula (iic), at least some of these components are bonded to each other, or hydrolyzed products of the alkoxysilane or metal alkoxides are bonded, thereby forming the weather resistant protective film.

Also, in the case where the above-described dehydration condensation reaction is carried out on a glass substrate, at least some of the hydrolyzed products of the above-described respective components can react with hydroxyl groups on the surface of the glass substrate to be strongly bonded to the glass substrate.

In the optical element according to the present disclosure, when the total content of the above-described alkoxysilane represented by the general formula (i) and the above-described one or more metal alkoxides selected from the general formula (iia) to the general formula (iic) is regarded as 100.0 mol %, the above-described weather resistant protective film preferably contains a hydrolysis and dehydration condensation product of 25.0 mol % or more and less than 80.0 mol % of the above-described alkoxysilane represented by the general formula (i) (or a partially hydrolyzed product thereof) with more than 20.0 mol % and 75.0 mol % or less of the above-described one or more metal alkoxides selected from the general formula (iia) to the general formula (iic), more preferably contains a hydrolysis and dehydration condensation product of 30.0 mol % to 77.5 mol % of the above-described alkoxysilane represented by the general formula (i) (or a partially hydrolyzed product thereof) with 22.5 mol % to 70.0 mol % of the above-described one or more metal alkoxides selected from the general formula (iia) to the general formula (iic), and still more preferably contains a hydrolysis and dehydration condensation product of 35.0 mol % to 75.0 mol % of the above-described alkoxysilane represented by the general formula (i) (or a partially hydrolyzed product thereof) with 25.0 mol % to 65.0 mol % of the above-described one or more metal alkoxides selected from the general formula (iia) to the general formula (iic).

In the optical element according to the present disclosure, when the mixing proportions of the above-described alkoxysilane represented by the general formula (i) (or a partially hydrolyzed product thereof) and the above-described one or more metal alkoxides selected from the general formula (iia) to the general formula (iic) are each within the above-described range, the weather resistant protective film that exhibits desired characteristics can be easily formed.

In the optical element according to the present disclosure, the above-described weather resistant protective film is preferably a hydrolysis and dehydration condensation product of a partially hydrolyzed product (represented by Si(OR¹) (OR²) (OR³)OH, etc.) obtained by partially hydrolyzing the above-described alkoxysilane represented by the general formula (i) in advance, with the above-described one or more metal alkoxides selected from the general formula (iia) to the general formula (iic).

The above-described alkoxysilane represented by the general formula (i) and the above-described metal alkoxides represented by the general formula (iia) to the general formula (iic) undergo hydrolysis in the presence of moisture to generate a silanol Si(OH)₄ and corresponding metal hydroxides, as mentioned above. Here, the above-described metal alkoxides represented by the general formula (iia) to the general formula (iic) (alkoxides of Ti, Zr, or Al) have significantly higher reactivity with water compared to the alkoxysilane represented by the general formula (i), and in the presence of water, they immediately produce metal hydroxides derived from the above-described metal alkoxides represented by the general formula (iia) to the general formula (iic) and also easily generate precipitates due to the subsequent polycondensation reaction, thus making it difficult for a homogeneous hydrolysis and polymerization reaction to occur.

In particular, in the case of attempting to form the weather resistant protective film using a coating solution containing a larger amount of the above-described metal alkoxides represented by the general formula (iia) to the general formula (iic) (alkoxides of Ti, Zr, and Al) compared to the above-described alkoxysilane represented by the general formula (i), it is difficult to form a homogeneous coating solution and/or coating film (weather resistant protective film) due to the above-described difference in reactivity.

Therefore, a partially hydrolyzed product (represented by Si(OR¹) (OR²) (OR³)OH, etc.) obtained by partially hydrolyzing the above-described alkoxysilane represented by the general formula (i) in advance is mixed with the above-described one or more metal alkoxides selected from the general formula (iia) to the general formula (iic) to form a homogeneous coating solution, which is then subjected to hydrolysis and dehydration condensation, thereby easily carrying out a homogeneous hydrolysis and dehydration condensation reaction.

As a result of such a homogeneous reaction proceeding, not only are hydrolyzed products of the above-described alkoxysilane represented by the general formula (i) bonded due to a dehydration condensation reaction, or hydrolyzed products of the above-described metal alkoxides represented by the general formula (iia) to the general formula (iic) bonded due to a dehydration condensation reaction, but also a hydrolyzed product of the above-described alkoxysilane represented by the general formula (i) undergoes a dehydration condensation reaction with hydrolyzed products of the above-described one or more metal alkoxides selected from compounds represented by the general formula (iia) to the general formula (iic). Then, at least some of these components are bonded to each other to form bonds such as Si—O—Al bond, Si—O—Ti bond, and Si—O—Zr bond, making it possible to easily form the desired weather resistant protective film.

In the optical element according to the present disclosure, the above-described alkoxysilane represented by the general formula (i) (or a partially hydrolyzed product thereof) and the above-described one or more metal alkoxides selected from the general formula (iia) to the general formula (iic) are preferably stirred for a predetermined time in the presence of a catalyst and an appropriate solvent, thereby forming a mixed solution (coating solution).

In the optical element according to the present disclosure, examples of the above-described catalyst may include one or more acids selected from hydrochloric acid, nitric acid, acetic acid, etc., and one or more bases selected from ammonia, sodium hydroxide, etc., in promoting the sol-gel reaction (hydrolysis reaction, polycondensation reaction).

In the optical element according to the present disclosure, there are no particular restrictions on the above-described solvent, as long as it is a solvent that can form a homogeneous coating solution in the end.

Examples of the above-described solvent may include one or more selected from alcohols such as methanol, ethanol, n-propanol, iso-propanol, and n-butanol, alkoxyalcohols such as 2-methoxyethanol and 2-ethoxyethanol, etc.

In the optical element according to the present disclosure, at the time of mixing the above-described alkoxysilane represented by the general formula (i) (or a partially hydrolyzed product thereof) with the above-described one or more metal alkoxides selected from the general formula (iia) to the general formula (iic), it is also possible to use a solvent or a stabilizer for the metal alkoxides.

Examples of the above-described stabilizer may include one or more selected from β-diketones such as acetylacetone and ethyl acetoacetate, alkanolamines such as monoethanolamine, diethanolamine, and triethanolamine, glycols such as ethylene glycol, propylene glycol, and diethylene glycol, etc.

In the optical element according to the present disclosure, it is preferable to mix the above-described alkoxysilane represented by the general formula (i) (or a partially hydrolyzed product thereof) with the above-described one or more metal alkoxides selected from the general formula (iia) to the general formula (iic) under a temperature of 0 to 200° C., more preferable to mix them under a temperature of 10 to 175° C., and still more preferable to mix them under a temperature of 15 to 150° C.

In the optical element according to the present disclosure, it is preferable to mix the above-described alkoxysilane represented by the general formula (i) (or a partially hydrolyzed product thereof) with the above-described one or more metal alkoxides selected from the general formula (iia) to the general formula (iic) by stirring for 1 minute to 24 hours to form a mixed solution, more preferable to mix them by stirring for 1 minute to 12 hours to form a mixed solution, and still more preferable to mix them by stirring for 1 minute to 6 minutes to form a mixed solution.

The above-described alkoxysilane represented by the general formula (i) (or a partially hydrolyzed product thereof) and the above-described one or more metal alkoxides selected from the general formula (iia) to the general formula (iic) are normally subjected to a hydrolysis and dehydration condensation reaction in a state where they coexist with the above-described catalyst and solvent used at the time of mixing.

As the coating solution (solution for forming weather resistant protective film), the mixed solution that contains the catalyst and solvent used at the time of mixing the above-described alkoxysilane represented by the general formula (i) (or a partially hydrolyzed product thereof) with the above-described one or more metal alkoxides selected from the general formula (iia) to the general formula (iic) is preferably used directly for the above-described hydrolysis and dehydration condensation reaction.

Specifically, it is preferable to apply a desired amount of the above-described mixed solution as the coating solution (solution for forming weather resistant protective film) to at least one main surface of a glass substrate formed of a phosphate glass or a fluorophosphate glass, and then to subject it to a heating treatment (baking treatment) at a predetermined temperature for a certain time, to allow metal elements M (Si, Ti, Zr, Al, etc.) in the coating solution (solution for forming weather resistant protective film) and constituent elements in the glass substrate M′ (semimetal and semiconductor elements such as P, Si, Ge, As, Se, Sn, Sb, Te, and Bi, and/or metal elements) to undergo a dehydration condensation reaction, dealcoholization condensation, etc., thereby forming metalloxane bonds M-O-M and/or M-O-M′ bonds.

There are no particular restrictions on the method for applying the above-described coating solution, and it can be selected as appropriate from the spin coat method (spin method), the nozzle flow method, the spray method, the dip method, the roll method, brush coating, etc.

There are no particular restrictions on the heating temperature when heating after applying a desired amount of the above-described coating solution to at least one main surface of the glass substrate, as long as it is at or above the temperature at which the solvent in the coating solution volatilizes and at or below the glass transition temperature of the glass substrate, and for example, 100 to 500° C. is appropriate.

Also, the heating time when heating after applying a desired amount of the above-described coating solution to at least one main surface of the glass substrate is preferably 1 minute to 24 hours, more preferably 3 minutes to 12 hours, and still more preferably 5 minutes to 6 hours.

As the heating temperature is higher when heating after applying a desired amount of the above-described coating solution to at least one main surface of the glass substrate, it is easier to form a weather resistant protective film that exhibits the excellent effects of improving weather resistance. However, for example, heating at a temperature higher than the glass transition temperature of the glass substrate tends to make the glass soften.

Also, as the heating time in hydrolysis and dehydration condensation reaction is longer, it is easier to form a weather resistant protective film that exhibits the excellent effects of improving weather resistance. However, if the heating time is too long, it is difficult to carry out an efficient heating treatment.

It is considered that the hydrolysis and dehydration condensation product obtained by the above-described reaction forms a coating film in which the above-described alkoxysilane represented by the general formula (i) and the above-described one or more metal alkoxides selected from the general formula (iia) to the general formula (iic) are not only bonded to each other but also strongly bonded to the glass substrate, and it is also considered that such a coating film functions as a protective film (weather resistant protective film) that can highly suppress weathering of the glass substrate even at high temperature and high humidity.

In the case where a SiO₂ film is formed on a glass substrate formed of a phosphate glass or a fluorophosphate glass by using the above-described alkoxysilane represented by the general formula (i) (or a partially hydrolyzed product thereof) and subjecting it to hydrolysis and dehydration condensation polymerization, Si—O—P bonds are formed between the SiO₂ film and the glass substrate.

Although the SiO₂ film inherently has high weather resistance, the above-described Si—O—P bonds formed between the SiO₂ film and the glass substrate have poor water resistance and are easily hydrolyzed and converted to Si—OH in the presence of water, resulting in the loss of bonding force with the glass substrate.

On the other hand, in the case where a metal oxide film is formed on a glass substrate formed of a phosphate glass or a fluorophosphate glass by subjecting the above-described metal alkoxides represented by the general formula (iia) to the general formula (iic) to hydrolysis and dehydration condensation polymerization, Ti—O—P bonds, Zr—O—P bonds, or Al—O—P bonds are formed between this metal oxide film and the glass substrate. These bonds have great water resistance and are unlikely to undergo a hydrolysis reaction, so that the bonding property to the glass substrate can be easily maintained.

Therefore, it is considered that a weather resistant protective film with excellent weather resistance can be easily formed by combining the above-described alkoxysilane represented by the general formula (i) (or a partially hydrolyzed product thereof) with the above-described one or more metal alkoxides selected from the general formula (iia) to the general formula (iic), and by subjecting them to a hydrolysis and dehydration condensation reaction.

A metal alkoxide to be combined with the above-described alkoxysilane represented by the general formula (i) (or a partially hydrolyzed product thereof) is preferably the above-described alkoxyaluminum represented by the general formula (iic).

Phosphorus atoms (P) constituting a phosphate glass or a fluorophosphate glass have a structure in which they are bonded to three crosslinking oxygen atoms (—O—) and one non-crosslinking oxygen atom (═O), as shown below. Among these oxygen atoms, the non-crosslinking oxygen (═O) does not form a stitch structure in the glass but loosens the structure of the glass, and it is thus considered that a phosphate glass or a fluorophosphate glass has low resistance to water.

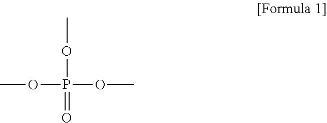

On the other hand, in a phosphate glass or a fluorophosphate glass, Al has a tetra-coordinate structure or a hexa-coordinate structure. Of such Al, Al with the tetra-coordinate structure functions to convert non-crosslinking oxygen (═O) of P to crosslinking oxygen (—O—), so that all oxygen atoms bonded to P become crosslinking oxygen (—O—) to form a dense glass stitch structure and strengthen the glass structure. In this manner, it is considered that water resistance of such phosphate glass or fluorophosphate glass is particularly improved.

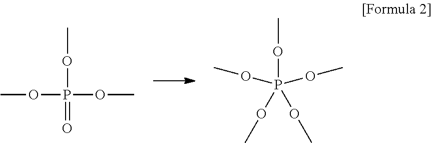

In the optical element according to the present disclosure, the thickness of the weather resistant protective film is preferably 1 nm to 5 μm, more preferably 10 nm to 2 μm, and still more preferably 20 nm to 1 μm.

Note that, herein, the thickness of the weather resistant protective film means the value found with a spectroscopic ellipsometer (M-20000V-Te manufactured by J.A. Woollam Company) for thicknesses of 1 μm or less, and with a stylus type ultra-precision roughness and film thickness profiler (Dektak 6M manufactured by Veeco Instruments Inc.) for thicknesses of more than 1 μm.

The optical element according to the present disclosure comprises, on at least one main surface of a glass substrate formed of a phosphate glass or a fluorophosphate glass, a weather resistant protective film having a monolayer structure.

Specifically, examples of forms of the optical element according to the present invention may include the following:

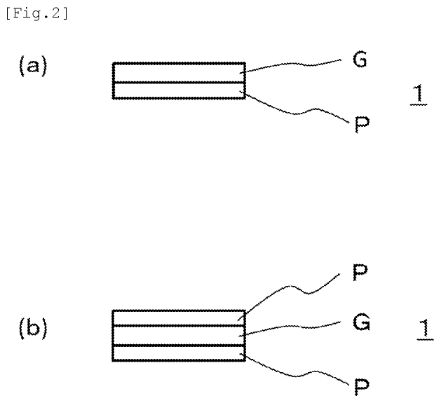

(1) an optical element 1 comprising a weather resistant protective film P on one main surface of a glass substrate G formed of a phosphate glass or a fluorophosphate glass, as illustrated in FIG. 2(a); and
(2) an optical element 1 comprising weather resistant protective films P, P on both main surfaces of a glass substrate G formed of a phosphate glass or a fluorophosphate glass, as illustrated in FIG. 2 (b).

Examples of forms of the optical element according to the present invention may also include those further comprising a resin film or an antireflection film on the above-described weather resistant protective film.

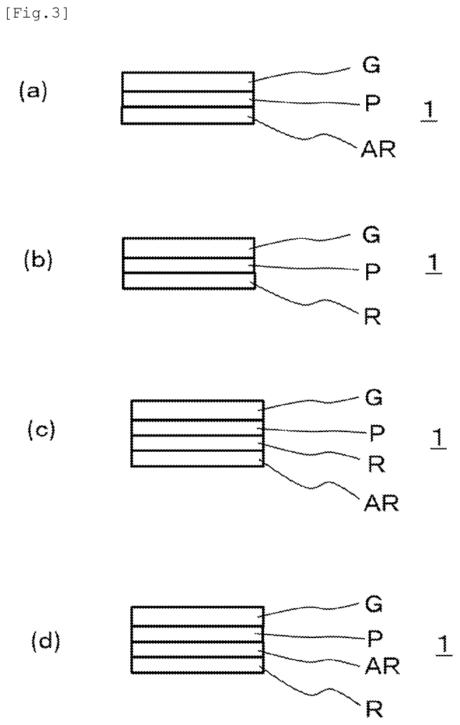

Specific examples thereof may include the following: (3) an optical element 1 comprising a weather resistant protective film P on one main surface of a glass substrate G formed of a phosphate glass or a fluorophosphate glass, and further comprising an antireflection film AR on such a weather resistant protective film P, as illustrated in FIG. 3(a); and (4) an optical element 1 comprising a weather resistant protective film P on one main surface of a glass substrate G formed of a phosphate glass or a fluorophosphate glass, and further comprising a resin film R on such a weather resistant protective film P, as illustrated in FIG. 3 (b).

Examples of forms of the optical element according to the present invention may further include those further comprising a resin film and an antireflection film in this order, or further comprising an antireflection film and a resin film in this order, on the above-described weather resistant protective film.

Specific examples thereof may include the following:

(5) an optical element 1 comprising a weather resistant protective film P on one main surface of a glass substrate G formed of a phosphate glass or a fluorophosphate glass, and further comprising a resin film R and an antireflection film AR in this order on such a weather resistant protective film P, as illustrated in FIG. 3(c); and
(6) an optical element 1 comprising a weather resistant protective film P on one main surface of a glass substrate G formed of a phosphate glass or a fluorophosphate glass, and further comprising an antireflection film AR and a resin film R in this order on such a weather resistant protective film P, as illustrated in FIG. 3(d).

In each optical element 1 shown in FIG. 2 and FIG. 3, it is preferable that the upper main surface and the lower main surface of the glass substrate P shown in each figure should serve as the light incident surface and the light emitting surface, respectively, when arranged.

In the optical elements 1 shown in FIG. 3(a) to FIG. 3(d), the upper main surface of the glass substrate G (the main surface opposite from the side on which the weather resistant protective film P is provided) may have the following features:

(7) no film may be formed, as illustrated in FIG. 3(a) to FIG. 3(d);
(8) a weather resistant protective film P may be further provided;
(9) a resin film R or a weather resistant protective film AR may be further provided via a weather resistant protective film P or without a weather resistant protective film P;
(10) a resin film R and an antireflection film AR may be further provided in this order, via a weather resistant protective film P or without a weather resistant protective film P; and
(11) an antireflection film AR and a resin film R may be further provided in this order, via a weather resistant protective film P or without a weather resistant protective film P.

In each of the above-mentioned embodiments, examples of the resin film include an absorbing resin film that absorbs ultraviolet light or near infrared light, a reflection amplifying film, a protective film for preventing weathering of glass, a strengthening film for improving the strength of glass, and a water repellent film.

Examples of the absorbing resin film that absorbs ultraviolet light or near infrared light may include those containing a near infrared absorbing dye and a transparent resin, and one containing a transparent resin and a near infrared absorbing dye uniformly dissolved or dispersed therein is preferable.

As the near infrared ray absorbing dye constituting the absorbing resin film, those conventionally known can be employed. It is more preferable to employ one or more selected from cyanine dyes, polymethine dyes, squarylium dyes, porphyrin dyes, metal dithiol complex dyes, phthalocyanine dyes, diimonium dyes, and inorganic oxide particles are preferable, and one or more selected from squarylium dyes, cyanine dyes, and phthalocyanine dyes.

As the resin constituting the resin film, transparent resins conventionally known can be employed. Examples thereof include one or more selected from acrylic resin, epoxy resin, ene-thiol resin, polycarbonate resin, polyether resin, polyarylate resin, polysulfone resin, polyethersulfone resin, polyparaphenylene resin, polyarylene ether phosphine oxide resin, polyimide resin, polyamideimide resin, polyolefin resin, cyclic olefin resin, and polyester resin.

As the transparent resin, those with a high glass transition point (Tg) are preferable in view of transparency, solubility of the near infrared ray absorbing dye in the transparent resin, and heat resistance. Specifically, it is preferable to employ one or more selected from polyester resin, polycarbonate resin, polyethersulfone resin, polyarylate resin, polyimide resin, and epoxy resin, and one or more selected from polyester resin and polyimide resin are more preferable.

As the polyester resin, one or more selected from polyethylene terephthalate resin and polyethylene naphthalate resin are preferable.

In addition to the above-described near infrared ray absorbing dye and transparent resin, the resin film may further contain optional components such as a color tone correcting dye, a leveling agent, an antistatic agent, a heat stabilizer, a light stabilizer, an antioxidant, a dispersing agent, a flame retardant, a lubricant, and a plasticizer, as long as the effects of the present disclosure are not impaired.

The resin film can be formed by, for example, dissolving or dispersing a dye and a transparent resin, as well as optionally compounded components, in a solvent to prepare a solution for forming a resin film, which is then applied, dried, and, if necessary, cured.

The above-described solution for forming a resin film may be one that contains a known surfactant, such as a cationic, anionic, or nonionic surfactant.

For the application of the solution for forming a resin film, it is possible to employ one or more coating methods selected from the dip coating method, the cast coating method, the spray coating method, the spin coating method, the nozzle flow coating method, the roll coating method, etc.

The resin film can be formed by applying the above-described solution for forming a resin film to a base material and then subjecting it to a drying treatment.

In each of the above-mentioned aspects, examples of the antireflection film may include one or more selected from monolayer films using a low refractive index substance such as MgF₂, multilayer films including SiO₂, etc. as a low refractive index substance and TiO₂, etc. as a high refractive index substance, and porous films formed of SiO₂ fine particles and a binder.

The antireflection film can be formed by, for example, any method selected from vapor phase methods such as the vapor deposition method, the sputtering method, and the CVD method, and liquid phase methods such as the dip coating method, the cast coating method, the spray coating method, the spin coating method, the nozzle flow coating method, and the roll coating method.

Examples of the optical element according to the present disclosure may include an optical filter such as an infrared cut filter (IRCF), as well as a lens, a prism, a diffraction grating, a substrate, etc., that constitute various optical instruments.

According to the present disclosure, there can be provided an optical element that can exhibit excellent weather resistance in spite of having a glass substrate formed of a phosphate glass or a fluorophosphate glass.

Next, the imaging device according to the present disclosure will be described.

The imaging device according to the present disclosure is characterized by comprising the optical element according to the present disclosure as an optical filter, together with a solid state imaging element and an imaging lens.

Examples of the solid state imaging element may include image sensors such as CCD (charge-coupled device) sensors and CMOS (complementary metal oxide semiconductor) sensors.

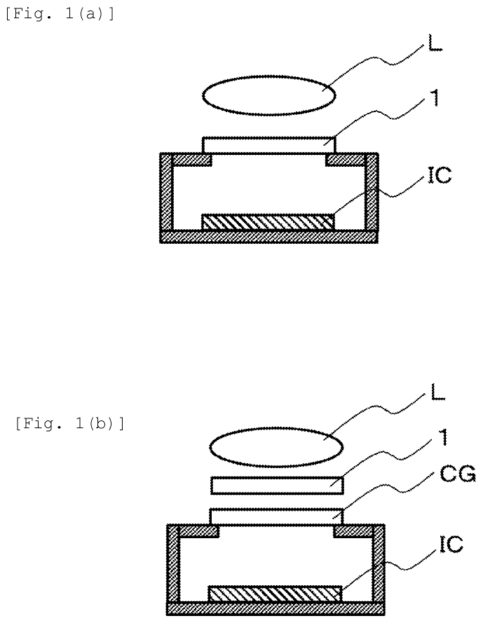

Examples of the configuration of the imaging device according to the present invention may include the camera module illustrated in FIG. 1.

FIG. 1(a) is a schematic illustration of a camera module pertaining to a compact digital camera installed in a smartphone or the like, and the camera module shown in FIG. 1(a) has one (or an integer n of one or more) lens L (or lenses Li, . . . , Ln), an optical filter 1 formed of the optical element according to the present disclosure, and an image sensor IC.

Also, FIG. 1(b) is a schematic illustration of a camera module pertaining to a digital single lens reflex camera, and the camera module shown in FIG. 1(b) has a lens L, an optical filter 1 formed of the optical element according to the present disclosure, a cover glass CG, and an image sensor IC.

According to the present disclosure, there can be provided an imaging device comprising, as an optical filter, an optical element that can exhibit excellent weather resistance in spite of having a glass substrate formed of a phosphate glass or a fluorophosphate glass.

### EXAMPLES

Hereinafter, the present disclosure will be further described with reference to Examples and Comparative Examples, but the present invention is not limited to the following Examples.

### Example 1

### 1. Preparation of Coating Solution

(1) In a container, 4.2 g of a 2.0 N (mol/L) aqueous HCl solution, 10.4 g of 2-propanol, and 17.8 g of 2-methoxyethanol were weighed and mixed under sealed conditions.
(2) 24.4 g of tetraethyl orthosilicate (Si(OC₂H₅)₄) was added to the above-described container, and the resultant was mixed at room temperature under sealed conditions for 30 minutes.
(3) 38.5 g of aluminum(III) tri-sec-butoxide (Al(OC₄H₉)₃) was further added to the above-described container, followed by heating under reflux for 1.5 hours. The heating was stopped and the mixture was cooled to about room temperature.
(4) A mixed solution of 21.1 g of a 2.0 N aqueous HCl solution and 194.0 g of 2-methoxyethanol was added to the above-described container under stirring, and the resultant was mixed at room temperature under sealed conditions for 10 minutes, thereby obtaining a clear and homogeneous coating solution (coating solution composition).

The obtained coating solution corresponds to one in which 42.9 mol % of tetraethyl orthosilicate and 57.1 mol % of aluminum(III) tri-sec-butoxide are mixed, when the total amount of tetraethyl orthosilicate and aluminum(III) tri-sec-butoxide added is regarded as 100 mol %.

Also, the solid concentration of the obtained coating solution, that is, the total content of tetraethyl orthosilicate and aluminum(III) tri-sec-butoxide, in terms of SiO₂ and Al₂O₃, respectively, in the coating solution was 5% by weight.

### 2. Formation of Coating Film

(1) The coating solution obtained in 1. was applied by dropping it onto one main surface of an absorbing glass substrate formed of a phosphate glass (CM500 manufactured by HOYA Corporation, thickness 0.59 mm), using a spin coater so as to achieve 10 μL/cm². Next, the glass substrate to which the coating solution had been applied was placed on a hot plate that had been heated to 135° C., heated for 3 minutes, and then naturally cooled.
(2) Thereafter, the above-described coating solution was applied by dropping it onto the main surface on the opposite side of the main surface to which the above-described coating solution had been applied, so as to achieve 10 μL/cm². Next, the glass substrate to which the coating solution had been applied was placed on a hot plate that had been heated to 200° C., and heated for 10 minutes.
(3) Thereafter, the above-described absorbing glass substrate, which had been coated with the coating solution on both main surfaces and subjected to the heating treatments, was subjected to a heating treatment in a muffle furnace at 280° C. for 10 minutes.

The above-described heating treatments of (1) to (3) caused dehydration condensation between hydroxyl groups on the glass substrate surface and hydroxyl groups of the components constituting the coating solution, or dehydration condensation between hydroxyl groups each other of the components constituting the coating solution, thereby fabricating a glass substrate having protective films each formed of a monolayer structure on both main surfaces (optical filter 1).

In the above-described protective films, the proportion of Al atoms in the total number of Al atoms and Si atoms is 57.1 atomic %, and the proportion of Si atoms in the total number of Al atoms and Si atoms is 42.9 atomic %.

Also, in the above-described protective films, when Al atoms and Si atoms are converted to Al₂O₃ and SiO₂, respectively, the proportion of Al₂O₃ in the total amount of Al₂O₃ and SiO₂ is 40.0 mol %, and the proportion of SiO₂ in the total amount of Al₂O₃ and SiO₂ is 60.0 mol %.

### Example 2

### 1. Preparation of Coating Solution

(1) In a container, 3.1 g of a 0.5N (mol/L) aqueous HCl solution, 10.4 g of 2-propanol, and 13.2 g of 2-methoxyethanol were weighed and mixed under sealed conditions.
(2) 36.0 g of tetraethyl orthosilicate (Si(OC₂H₅)₄) was added to the above-described container, and the resultant was mixed at room temperature under sealed conditions for 30 minutes.
(3) 19.6 g of titanium(IV) tetra-n-butoxide (Ti(OC₄H₉)₄) was further added to the above-described container, and the resultant was mixed at room temperature under sealed conditions for 30 minutes.
(4) A mixed solution of 30.1 g of a 0.5N aqueous HCl solution, 82.8 g of 2-propanol, and 104.8 g of 2-methoxyethanol was added to the above-described container under stirring, and the resultant was mixed at room temperature under sealed conditions for 30 minutes, thereby obtaining a clear and homogeneous coating solution (coating solution composition).

The obtained coating solution corresponds to one in which 75.0 mol % of tetraethyl orthosilicate and 25.0 mol % of titanium(IV) tetra-n-butoxide are mixed, when the total amount of tetraethyl orthosilicate and titanium(IV) tetra-n-butoxide added is regarded as 100 mol %.

Also, the solid concentration of the obtained coating solution, that is, the total content of tetraethyl orthosilicate and titanium(IV) tetra-n-butoxide, in terms of SiO₂ and TiO₂, respectively, in the coating solution was 5% by weight.

### 2. Formation of Coating Film

A glass substrate having protective films each formed of a monolayer structure on both main surfaces of the glass substrate formed of a phosphate glass (CM500 manufactured by HOYA Corporation, thickness 0.59 mm) (optical filter 2) was fabricated in the same manner as in Example 1, except for using the obtained coating solution as described above.

In the above-described protective films, the proportion of Ti atoms in the total number of Ti atoms and Si atoms was 25.0 atomic %, and the proportion of Si atoms in the total number of Ti atoms and Si atoms was 75.0 atomic %.

Also, in the above-described protective films, when Ti atoms and Si atoms are converted to TiO₂ and SiO₂, respectively, the proportion of TiO₂ in the total amount of TiO₂ and SiO₂ was 25.0 mol %, and the proportion of SiO₂ in the total amount of TiO₂ and SiO₂ was 75.0 mol %.

### Example 3

### 1. Preparation of Coating Solution

(1) In a container, 4.8 g of a 1.0N (mol/L) aqueous HCl solution and 20.2 g of 2-methoxyethanol were weighed and mixed under sealed conditions.
(2) 27.7 g of tetraethyl orthosilicate (Si(OC₂H₅)₄) was added to the above-described container, and the resultant was mixed at room temperature under sealed conditions for 30 minutes.
(3) 25.7 g of an 85% solution of zirconium(IV) tetra-n-butoxide (Zr(OC₄H₉)₄) in n-butanol was further added to the above-described container, and the resultant was mixed at room temperature under sealed conditions for 30 minutes.
(4) A mixed solution of 22.6 g of a 1.0N aqueous HCl solution and 199.0 g of 2-methoxyethanol was added to the above-described container under stirring, and the resultant was mixed at room temperature under sealed conditions for 30 minutes, thereby obtaining a clear and homogeneous coating solution (coating solution composition).

The obtained coating solution corresponds to one in which 70.0 mol % of tetraethyl orthosilicate and 30.0 mol % of zirconium(IV) tetra-n-butoxide are mixed, when the total amount of tetraethyl orthosilicate and zirconium(IV) tetra-n-butoxide added is regarded as 100 mol %.

Also, the solid concentration of the obtained coating solution, that is, the total content of tetraethyl orthosilicate and zirconium(IV) tetra-n-butoxide in the coating solution when tetraethyl orthosilicate and zirconium(IV) tetra-n-butoxide, in terms of SiO₂ and ZrO₂, respectively, in the coating solution was 5% by weight.

### 2. Formation of Coating Film

A glass substrate having protective films each formed of a monolayer structure on both main surfaces of the glass substrate formed of a phosphate glass (CM500 manufactured by HOYA Corporation, thickness 0.59 mm) (optical filter 3) was fabricated in the same manner as in Example 1, except for using the obtained coating solution as described above.

In the above-described protective films, the proportion of Zr atoms in the total number of Zr atoms and Si atoms is 30.0 atomic %, and the proportion of Si atoms in the total number of Zr atoms and Si atoms is 70.0 atomic %.

Also, in the above-described protective films, when zirconium atoms and Si atoms are converted to ZrO₂ and SiO₂, respectively, the proportion of ZrO₂ in the total amount of ZrO₂ and SiO₂ is 30.0 mol %, and the proportion of SiO₂ in the total amount of ZrO₂ and SiO₂ is 70.0 mol %.

### Example 4

### 1. Preparation of Coating Solution

A clear and homogeneous coating solution (coating solution composition) was obtained in the same manner as in Example 1, except that 21.6 g of tetraethyl orthosilicate (Si(OC₂H₅)₄) and 12.3 g of methyltriethoxysilane (CH₃Si(OC₂H₅)₃) were used instead of 36.0 g of tetraethyl orthosilicate (Si(OC₂H₅)₄) in “1. Preparation of coating solution” (2) of Example 1.

The obtained coating solution corresponds to one in which 75.0 mol % of tetraethyl orthosilicate and methyltriethoxysilane in total and 25.0 mol % of titanium(IV) tetra-n-butoxide are mixed, when the total amount of tetraethyl orthosilicate, methyltriethoxysilane, and titanium(IV) tetra-n-butoxide added is regarded as 100 mol %.

Also, the solid concentration of the obtained coating solution, that is, the total content of tetraethyl orthosilicate, methyltriethoxysilane, and titanium(IV) tetra-n-butoxide, in terms of SiO₂, SiO₂, and TiO₂, respectively, in the coating solution was 5% by weight.

### 2. Formation of Coating Film

A glass substrate having protective films each formed of a monolayer structure on both main surfaces of the glass substrate formed of a phosphate glass (CM500 manufactured by HOYA Corporation, thickness 0.59 mm) (optical filter 4) was fabricated in the same manner as in Example 1, except for using the obtained coating solution as described above.

In the above-described protective films, the proportion of Ti atoms in the total number of Ti atoms and Si atoms is 25.0 atomic %, and the proportion of Si atoms in the total number of Ti atoms and Si atoms is 75.0 atomic %.

Also, in the above-described protective films, when Ti atoms and Si atoms are converted to TiO₂ and SiO₂, respectively, the proportion of TiO₂ in the total amount of TiO₂ and SiO₂ is 25.0 mol %, and the proportion of SiO₂ in the total amount of TiO₂ and SiO₂ is 75.0 mol %.

### Example 5

### 1. Preparation of Coating Solution

A clear and homogeneous coating solution (coating solution composition) was obtained in the same manner as in Example 1, except that 14.0 g of tetramer of titanium(IV) tetra-n-butoxide (Ti(OC₄H₉)₄) was used instead of 19.6 g of titanium(IV) tetra-n-butoxide (Ti(OC₄H₉)₄) in “1. Preparation of coating solution” (3) of Example 1.

The obtained coating solution corresponds to one in which 75.0 mol % of tetraethyl orthosilicate and 25.0 mol % of tetramer of titanium(IV) tetra-n-butoxide are mixed, when the total amount of tetraethyl orthosilicate and tetramer of titanium(IV) tetra-n-butoxide added is regarded as 100 mol %.

Also, the solid concentration of the obtained coating solution, that is, the total content of tetraethyl orthosilicate and tetramer of titanium(IV) tetra-n-butoxide, in terms of SiO₂ and TiO₂, respectively, in the coating solution was 5% by weight.

### 2. Formation of Coating Film

A glass substrate having protective films each formed of a monolayer structure on both main surfaces of the glass substrate formed of a phosphate glass (CM500 manufactured by HOYA Corporation, thickness 0.59 mm) (optical filter 5) was fabricated in the same manner as in Example 1, except for using the obtained coating solution as described above.

In the above-described protective films, the proportion of Ti atoms in the total number of Ti atoms and Si atoms is 25.0 atomic %, and the proportion of Si atoms in the total number of Ti atoms and Si atoms is 75.0 atomic %.

Also, in the above-described protective films, when Ti atoms and Si atoms are converted to TiO₂ and SiO₂, respectively, the proportion of TiO₂ in the total amount of TiO₂ and SiO₂ is 25.0 mol %, and the proportion of SiO₂ in the total amount of TiO₂ and SiO₂ is 75.0 mol %.

### Example 6

### 1. Preparation of Coating Solution

A clear and homogeneous coating solution (coating solution composition) was obtained in the same manner as in Example 1, except that 30.2 g of tetraethyl orthosilicate was used instead of 36.0 g of tetraethyl orthosilicate in “1. Preparation of coating solution” (2) of Example 1, and that 10.6 g of titanium(IV) tetra-n-butoxide (Ti(OC₄H₉)₄) and 14.0 g of an 85% solution of zirconium(IV) tetra-n-butoxide in n-butanol were used instead of 19.6 g of titanium(IV) tetra-n-butoxide (Ti(OC₄H₉)₄) in “1. Preparation of coating solution” (3) of Example 1.

The obtained coating solution corresponds to one in which 70.0 mol % of tetraethyl orthosilicate, 15.0 mol % of titanium(IV) tetra-n-butoxide, and 15.0 mol % of zirconium(IV) tetra-n-butoxide are mixed, when the total amount of tetraethyl orthosilicate, titanium(IV) tetra-n-butoxide, and zirconium(IV) tetra-n-butoxide added is regarded as 100 mol %.

Also, the solid concentration of the obtained coating solution, that is, the total content of tetraethyl orthosilicate, titanium(IV) tetra-n-butoxide, and zirconium(IV) tetra-n-butoxide, in terms of SiO₂, TiO₂, and ZrO₂, respectively, in the coating solution was 5% by weight.

### 2. Formation of Coating Film

A glass substrate having protective films each formed of a monolayer structure on both main surfaces of the glass substrate formed of a phosphate glass (CM500 manufactured by HOYA Corporation, thickness 0.59 mm) (optical filter 6) was fabricated in the same manner as in Example 1, except for using the obtained coating solution as described above.

In the above-described protective films, the proportion of Ti atoms in the total number of Ti atoms, Zr atoms, and Si atoms is 15.0 atomic %, the proportion of Zr atoms in the total number of Ti atoms, Zr atoms, and Si atoms is 15.0 atomic %, and the proportion of Si atoms in the total number of Ti atoms, Zr atoms, and Si atoms is 70.0 atomic %.

Also, in the above-described protective films, when Ti atoms, Zr atoms, and Si atoms are converted to TiO₂, ZrO₂, and SiO₂, respectively, the proportion of TiO₂ in the total amount of TiO₂, ZrO₂, and SiO₂ is 15.0 mol %, the proportion of ZrO₂ in the total amount of TiO₂, ZrO₂, and SiO₂ is 15.0 mol %, and the proportion of SiO₂ in the total amount of TiO₂, ZrO₂, and SiO₂ is 70.0 mol %.

### Example 7

### 1. Preparation of Coating Solution

A clear and homogeneous coating solution (coating solution composition) was obtained in the same manner as in Example 1, except that 27.6 g of tetraethyl orthosilicate was used instead of 36.0 g of tetraethyl orthosilicate in “1. Preparation of coating solution” (2) of Example 1, and that 30.0 g of titanium(IV) tetra-n-butoxide (Ti(OC₄H₉)₄) was used instead of 19.6 g of titanium(IV) tetra-n-butoxide (Ti (OC₄H₉)₄) in “1. Preparation of coating solution” (3) of Example 1.

The obtained coating solution corresponds to one in which 60.0 mol % of tetraethyl orthosilicate and 40.0 mol % of titanium(IV) tetra-n-butoxide are mixed, when the total amount of tetraethyl orthosilicate and titanium(IV) tetra-n-butoxide added is regarded as 100 mol %. Also, the solid concentration of the obtained coating solution, that is, the total content of tetraethyl orthosilicate and titanium(IV) tetra-n-butoxide, in terms of SiO₂ and TiO₂, respectively, in the coating solution was 5% by weight.

### 2. Formation of Coating Film

A glass substrate having protective films each formed of a monolayer structure on both main surfaces of the glass substrate formed of a phosphate glass (CM500 manufactured by HOYA Corporation, thickness 0.59 mm) (optical filter 7) was fabricated in the same manner as in Example 1, except for using the obtained coating solution as described above.

In the above-described protective films, the proportion of Ti atoms in the total number of Ti atoms and Si atoms is 40.0 atomic %, and the proportion of Si atoms in the total number of Ti atoms and Si atoms is 60.0 atomic %.

Also, in the above-described protective films, when Ti atoms and Si atoms are converted to TiO₂ and SiO₂, respectively, the proportion of TiO₂ in the total amount of TiO₂ and SiO₂ is 40.0 mol %, and the proportion of SiO₂ in the total amount of TiO₂ and SiO₂ is 60.0 mol %.

### Example 8

### 1. Preparation of Coating Solution

A clear and homogeneous coating solution (coating solution composition) was obtained in the same manner as in Example 1, except that 22.3 g of tetraethyl orthosilicate was used instead of 36.0 g of tetraethyl orthosilicate in “1. Preparation of coating solution” (2) of Example 1, and that 36.5 g of titanium(IV) tetra-n-butoxide (Ti(OC₄H₉)₄) was used instead of 19.6 g of titanium(IV) tetra-n-butoxide (Ti (OC₄H₉)₄) in “1. Preparation of coating solution” (3) of Example 1.

The obtained coating solution corresponds to one in which 50.0 mol % of tetraethyl orthosilicate and 50.0 mol % of titanium(IV) tetra-n-butoxide are mixed, when the total amount of tetraethyl orthosilicate and titanium(IV) tetra-n-butoxide added is regarded as 100 mol %.

Also, the solid concentration of the obtained coating solution, that is, the total content of tetraethyl orthosilicate and titanium(IV) tetra-n-butoxide, in terms of SiO₂ and TiO₂, respectively, in the coating solution was 5% by weight.

### 2. Formation of Coating Film

A glass substrate having protective films each formed of a monolayer structure on both main surfaces of the glass substrate formed of a phosphate glass (CM500 manufactured by HOYA Corporation, thickness 0.59 mm) (optical filter 8) was fabricated in the same manner as in Example 1, except for using the obtained coating solution as described above.

In the above-described protective films, the proportion of Ti atoms in the total number of Ti atoms and Si atoms is 50.0 atomic %, and the proportion of Si atoms in the total number of Ti atoms and Si atoms is 50.0 atomic %.

Also, in the above-described protective films, when Ti atoms and Si atoms are converted to TiO₂ and SiO₂, respectively, the proportion of TiO₂ in the total amount of TiO₂ and SiO₂ is 50.0 mol %, and the proportion of SiO₂ in the total amount of TiO₂ and SiO₂ is 50.0 mol %.

### Example 9

### 1. Preparation of Coating Solution

A clear and homogeneous coating solution (coating solution composition) was obtained in the same manner as in Example 2, except that 17.0 g of tetraethyl orthosilicate was used instead of 27.7 g of tetraethyl orthosilicate in “1. Preparation of coating solution” (2) of Example 2, and that 36.9 g of an 85% solution of zirconium(IV) tetra-n-butoxide in butanol was used instead of 25.7 g of the 85% solution of zirconium(IV) tetra-n-butoxide in butanol in “1. Preparation of coating solution” (3) of Example 2.

The obtained coating solution corresponds to one in which 50.0 mol % of tetraethyl orthosilicate and 50.0 mol % of zirconium(IV) tetra-n-butoxide are mixed, when the total amount of tetraethyl orthosilicate and zirconium(IV) tetra-n-butoxide added is regarded as 100 mol %.

Also, the solid concentration of the obtained coating solution, that is, the total content of tetraethyl orthosilicate and zirconium(IV) tetra-n-butoxide, in terms of SiO₂ and ZrO₂, respectively, in the coating solution was 5% by weight.

### 2. Formation of Coating Film

A glass substrate having protective films each formed of a monolayer structure on both main surfaces of the glass substrate formed of a phosphate glass (CM500 manufactured by HOYA Corporation, thickness 0.59 mm) (optical filter 9) was fabricated in the same manner as in Example 1, except for using the obtained coating solution as described above.

In the above-described protective films, the proportion of Zr atoms in the total number of Zr atoms and Si atoms is 50.0 atomic %, and the proportion of Si atoms in the total number of Zr atoms and Si atoms is 50.0 atomic %.

Also, in the above-described protective films, when Zr atoms and Si atoms are converted to ZrO₂ and SiO₂, respectively, the proportion of ZrO₂ in the total amount of ZrO₂ and SiO₂ is 50.0 mol %, and the proportion of SiO₂ in the total amount of ZrO₂ and SiO₂ is 50.0 mol %.

### Example 10

### 1. Preparation of Coating Solution

A clear and homogeneous coating solution (coating solution composition) was obtained in the same manner as in Example 3, except that 36.5 g of tetraethyl orthosilicate was used instead of 36.0 g of tetraethyl orthosilicate in “1. Preparation of coating solution” (2) of Example 3, and that 21.6 g of aluminum(III) tri-sec-butoxide was used instead of 38.5 g of aluminum(III) tri-sec-butoxide in “1. Preparation of coating solution” (3) of Example 3.

The obtained coating solution corresponds to one in which 66.7 mol % of tetraethyl orthosilicate and 33.3 mol % of aluminum(III) tri-sec-butoxide are mixed, when the total amount of tetraethyl orthosilicate and aluminum(III) tri-sec-butoxide added is regarded as 100 mol %.

Also, the solid concentration of the obtained coating solution, that is, the total content of tetraethyl orthosilicate and aluminum(III) tri-sec-butoxide, in terms of SiO₂ and Al₂O₃, respectively, in the coating solution was 5% by weight.

### 2. Formation of Coating Film

A glass substrate having protective films each formed of a monolayer structure on both main surfaces of the glass substrate formed of a phosphate glass (CM500 manufactured by HOYA Corporation, thickness 0.59 mm) (optical filter 10) was fabricated in the same manner as in Example 1, except for using the obtained coating solution as described above.

In the above-described protective films, the proportion of Al atoms in the total number of Al atoms and Si atoms is 33.3 atomic %, and the proportion of Si atoms in the total number of Al atoms and Si atoms is 66.7 atomic %.

Also, in the above-described protective films, when Al atoms and Si atoms are converted to Al₂O₃ and SiO₂, respectively, the proportion of Al₂O₃ in the total amount of Al₂O₃ and SiO₂ is 20.0 mol %, and the proportion of SiO₂ in the total amount of Al₂O₃ and SiO₂ is 80.0 mol %.

### Comparative Example 1

In this example, the glass substrate formed of a phosphate glass (CM500 manufactured by HOYA Corporation, thickness 0.59 mm) used in Example 1 was used as a comparative optical filter 1 without forming a coating film.

### Comparative Example 2

### 1. Preparation of Coating Solution

A clear and homogeneous coating solution (coating solution composition) was obtained in the same manner as in Example 1, except that 45.3 g of tetraethyl orthosilicate was used instead of 36.0 g of tetraethyl orthosilicate in “1. Preparation of coating solution” (2) of Example 1, and that 8.2 g of titanium(IV) tetra-n-butoxide (Ti(OC₄H₉)₄) was used instead of 19.6 g of titanium(IV) tetra-n-butoxide (Ti (OC₄H₉)₄) in “1. Preparation of coating solution” (3) of Example 1.

The obtained coating solution corresponds to one in which 90.0 mol % of tetraethyl orthosilicate and 10.0 mol % of titanium(IV) tetra-n-butoxide are mixed, when the total amount of tetraethyl orthosilicate and titanium(IV) tetra-n-butoxide added is regarded as 100 mol %.

Also, the solid concentration of the obtained coating solution, that is, the total content of tetraethyl orthosilicate and titanium(IV) tetra-n-butoxide, in terms of SiO₂ and TiO₂, respectively, in the coating solution was 5% by weight.

### 2. Formation of Coating Film

A glass substrate having protective films each formed of a monolayer structure on both main surfaces of the glass substrate formed of a phosphate glass (CM500 manufactured by HOYA Corporation, thickness 0.59 mm) (comparative optical filter 2) was fabricated in the same manner as in Example 1, except for using the obtained coating solution as described above.

In the above-described protective films, the proportion of Ti atoms in the total number of Ti atoms and Si atoms is 10.0 atomic %, and the proportion of Si atoms in the total number of Ti atoms and Si atoms is 90.0 atomic %.

Also, in the above-described protective films, when Ti atoms and Si atoms are converted to TiO₂ and SiO₂, respectively, the proportion of TiO₂ in the total amount of TiO₂ and SiO₂ is 10.0 mol %, and the proportion of SiO₂ in the total amount of TiO₂ and SiO₂ is 90.0 mol %.

### Comparative Example 3

### 1. Preparation of Coating Solution

A clear and homogeneous coating solution (coating solution composition) was obtained in the same manner as in Example 1, except that 40.2 g of tetraethyl orthosilicate was used instead of 36.0 g of tetraethyl orthosilicate in “1. Preparation of coating solution” (2) of Example 1, and that 14.5 g of titanium(IV) tetra-n-butoxide (Ti(OC₄H₉)₄) was used instead of 19.6 g of titanium(IV) tetra-n-butoxide (Ti (OC₄H₉)₄) in “1. Preparation of coating solution” (3) of Example 1.

The obtained coating solution corresponds to one in which 82.0 mol % of tetraethyl orthosilicate and 18.0 mol % of titanium(IV) tetra-n-butoxide are mixed, when the total amount of tetraethyl orthosilicate and titanium(IV) tetra-n-butoxide added is regarded as 100 mol %.

Also, the solid concentration of the obtained coating solution, that is, the total content of tetraethyl orthosilicate and titanium(IV) tetra-n-butoxide, in terms of SiO₂ and TiO₂, respectively, in the coating solution was 5% by weight.

### 2. Formation of Coating Film

A glass substrate having protective films each formed of a monolayer structure on both main surfaces of the glass substrate formed of a phosphate glass (CM500 manufactured by HOYA Corporation, thickness 0.59 mm) (comparative optical filter 3) was fabricated in the same manner as in Example 1, except for using the obtained coating solution as described above.

In the above-described protective films, the proportion of Ti atoms in the total number of Ti atoms and Si atoms is 18.0 atomic %, and the proportion of Si atoms in the total number of Ti atoms and Si atoms is 82.0 atomic %.

Also, in the above-described protective films, when Ti atoms and Si atoms are converted to TiO₂ and SiO₂, respectively, the proportion of TiO₂ in the total amount of TiO₂ and SiO₂ is 18.0 mol %, and the proportion of SiO₂ in the total amount of TiO₂ and SiO₂ is 82.0 mol %.

### <Evaluation of Weather Resistance>

In the optical filters obtained in the above-described Examples and Comparative Examples, weather resistance was evaluated in terms of the degree of cloudiness on the basis of the haze values shown below.

### (Evaluation Method)

### (1) Weather Resistance Life 1

A test piece cut out from each optical filter was exposed to an environment at a temperature of 65° C. and a relative humidity of 90% in a thermo-hygrostat chamber, and in such a state, observation of the appearance and measurement of the degree of cloudiness (haze value) with a haze meter were made on the surface of the weather resistant protective film provided, after 10 hours, after 20 hours, after 30 hours, after 40 hours, after 50 hours, after 75 hours, after 100 hours, after 150 hours, after 200 hours, after 250 hours, after 300 hours, after 350 hours, after 400 hours, after 500 hours, after 750 hours, and after 1000 hours from the initiation of exposure.

It is considered that the degree of cloudiness at which the optical filter gets clouded and begins to pose a problem for use is a haze value of 0.2. Accordingly, the exposure time for measurement immediately before the exposure time at which the haze value first reaches a value of 0.2 or more was considered to be the limit for a haze value of 0.2 or less, and this was defined as the weather resistance life (the limit time for weather resistance). Then, the exposure time pertaining to this weather resistance life was determined for each (for example, in the case where the haze value first exceeds 0.2 after 500 hours from the above-described initiation of exposure, the weather resistance life of that optical filter is 400 hours).

In the case where the haze value after 1000 hours from the above-described initiation of exposure was less than 0.2, the exposure time pertaining to the weather resistance life was considered to be 1000 hours.

### (2) Weather Resistance Life 2

Evaluation was performed in the same manner as in (1) Weather resistance life 1, except that a test piece cut out from each optical filter was exposed to an environment at a temperature of 85° C. and a relative humidity of 85% in a thermo-hygrostat chamber, to determine the weather resistance life.

The results for each of the Examples and Comparative Examples are shown in Table 1.

TABLE 1

| | | | Example | Example | Example | Example | Example | Example | Example |
|---|---|---|---|---|---|---|---|---|---|
| | | | 1 | 2 | 3 | 4 | 5 | 6 | 7 |
| Whether protective film | | | Yes | Yes | Yes | Yes | Yes | Yes | Yes |
| Glass substrate | | | CM500 | CM500 | CM500 | CM500 | CM500 | CM500 | CM500 |
| Coating | mol % in | TiO₂ | — | 25.0 | — | 25.0 | 25.0 | 15.0 | 40.0 |
| solution | terms of | ZrO₂ | — | — | 30.0 | — | — | 15.0 | — |
| | oxide | Al₂O₃ | 40.0 | — | — | — | — | — | — |
| | | SiO₂** | 60.0 | 75.0 | 70.0 | 75.0 | 75.0 | 70.0 | 60.0 |
| Protective | atomic % | Ti | — | 25.0 | — | 25.0 | 25.0 | 15.0 | 40.0 |
| film | | Zr | — | — | 30.0 | — | — | 15.0 | — |
| | | Al | 57.1 | — | — | — | — | — | — |
| | | Si | 42.9 | 75.0 | 70.0 | 75.0 | 75.0 | 70.0 | 60.0 |
| | mol % in | TiO₂ | — | 25.0 | — | 25.0 | 25.0 | 15.0 | 40.0 |
| | terms of | ZrO₂ | — | — | 30.0 | — | — | 15.0 | — |
| | oxide | Al₂O₃ | 40.0 | — | — | — | — | — | — |
| | | SiO₂ | 60.0 | 75.0 | 70.0 | 75.0 | 75.0 | 70.0 | 60.0 |

| | | | | | | | | |
|---|---|---|---|---|---|---|---|---|
| Weather | Weather resistance life 1 | 1000 hr | 500 hr | 750 hr | 500 hr | 500 hr | 750 hr | 750 hr |
| resistance | 65° C./90% | | | | | | | |
| | Weather resistance life 2 | 350 hr | 150 hr | 250 hr | 200 hr | 200 hr | 250 hr | 250 hr |
| | 85° C./85% | | | | | | | |

| | | | Example | Example | Example | Comparative | Comparativa | Comparative |
|---|---|---|---|---|---|---|---|---|
| | | | 8 | 9 | 10 | Example 1 | Example 2 | Example 3 |
| Whether protective film | | | Yes | Yes | Yes | Yes | Yes | Yes |
| Glass substrate | | | CM500 | CM500 | CM500 | CM500 | CM500 | CM500 |
| Coating | mol % in | TiO₂ | 50.0 | — | — | — | 10.0 | 18.0 |
| solution | terms of | ZrO₂ | — | 50.0 | — | — | — | — |
| | oxide | Al₂O₃ | — | — | 20.0 | — | — | — |
| | | SiO₂** | 50.0 | 50.0 | 80.0 | — | 90.0 | 82.0 |
| Protective | atomic % | Ti | 50.0 | — | — | — | 10.0 | 18.0 |
| film | | Zr | — | 50.0 | — | — | — | — |
| | | Al | — | — | 33.3 | — | — | — |
| | | Si | 50.0 | 50.0 | 66.7 | — | 90.0 | 82.0 |
| | mol % in | TiO₂ | 50.0 | — | — | — | 10.0 | 18.0 |
| | terms of | ZrO₂ | — | 50.0 | — | — | — | — |
| | oxide | Al₂O₃ | — | — | 20.0 | — | — | — |
| | | SiO₂ | 50.0 | 50.0 | 80.0 | — | 90.0 | 82.0 |

| | | | | | | | |
|---|---|---|---|---|---|---|---|
| Weather | Weather resistance life 1 | 750 hr | 1000 hr | 750 hr | <10 hr* | 50 hr | 150 hr |
| resistance | 65° C./90% | | | | | | |
| | Weather resistance life 2 | 300 hr | 350 hr | 250 hr | <5 hr* | 10 hr | 40 hr |
| | 85° C./85% | | | | | | |

*In the table, “<10 hr” means less than 10 hours and “<5 hr” means less than 5 hours.
***As the Si atom source, tetraethyl orthosilicate and methyltriethoxysilane were used in Example 4, and tetraethyl orthosilicate was used in the other Examples.

### Example 11

### 1. Preparation of Coating Solution

A clear and homogeneous coating solution (coating olution composition) was obtained in the same manner as in Example 1, except that 30.1 g of tetraethyl orthosilicate was used instead of 24.4 g of tetraethyl orthosilicate in “1. Preparation of coating solution” (2) of Example 1, and that 30.5 g of aluminum(III) tri-sec-butoxide was used instead of 38.5 g of aluminum(III) tri-sec-butoxide in “1. Preparation of coating solution” (3) of Example 1.

The obtained coating solution corresponds to one in which 53.8 mol % of tetraethyl orthosilicate and 46.2 mol % of aluminum(III) tri-sec-butoxide are mixed, when the total amount of tetraethyl orthosilicate and aluminum(III) tri-sec-butoxide added is regarded as 100 mol %.

Also, the solid concentration of the obtained coating solution, that is, the total content of tetraethyl orthosilicate and aluminum(III) tri-sec-butoxide, in terms of SiO₂ and Al₂O₃, respectively, in the coating solution was 5% by weight.

### 2. Formation of Coating Film

A glass substrate having protective films each formed of a monolayer structure on both main surfaces of the glass substrate formed of a phosphate glass (CM500 manufactured by HOYA Corporation, thickness 0.59 mm) (optical filter 11) was fabricated in the same manner as in Example 1, except for using the obtained coating solution as described above.

In the above-described protective films, the proportion of Al atoms in the total number of Al atoms and Si atoms is 46.2 atomic %, and the proportion of Si atoms in the total number of Al atoms and Si atoms is 53.8 atomic %.

Also, in the above-described protective films, when Al atoms and Si atoms are converted to Al₂O₃ and SiO₂, respectively, the proportion of Al₂O₃ in the total amount of Al₂O₃ and SiO₂ is 30.0 mol %, and the proportion of SiO₂ in the total amount of Al₂O₃ and SiO₂ is 70.0 mol %.

### <Confirmation of Chemical Bond (Al—O—Si Bond)>

(1) 13.5 g of the coating solution prepared in the above-described 1. was poured into a petri dish made of polymethylpentene with an inner diameter of 85 mm and a depth of 15 mm, and the dish containing the coating solution was covered with a lid, and left to stand in a thermostat chamber at an internal temperature of 60° C. so that the coating solution was gelled and dried to form a plate-like sample with a thickness of 0.5 mm.
(2) The plate-like sample obtained in (1) was subjected to a heat treatment in a muffle furnace at 280° C. for 10 minutes, thereby obtaining a measurement sample.
(3) Using a microscopic FT-IR (Excalibur+UMA600 manufactured by Digital Lab), FT-IR measurement on the measurement sample obtained in (2) was carried out in the following measurement conditions.

### Measurement Conditions

Measurement mode: transmission mode
Measurement range: 500 to 1000 cm⁻¹
Number of scans: 128
Resolution: 4 cm⁻¹
Scan speed: 5 kHz
   (4) As a result of the above-described FT-IR measurement by (3), absorption peaks were exhibited at 555 cm⁻¹, 852 cm⁻¹, and 911 cm⁻¹.

In J Sol-Gel Sci Technol (2010) 56: 47-52, authored by N. P. Damayanti, “Preparation of Superhydrophobic PET fabric from Al₂O₃—SiO₂ hybrid: geometrical approach to create high contact angle surface from low contact angle material”, it was reported that, when FT-IR measurement is performed, absorption peaks due to Si—O—Al bonds are detected at 557 cm⁻¹, 850 cm⁻¹, and 902 cm⁻¹ (see FIG. 4 and the right column on p. 51 of the above-described literature).

For the measurement sample used in this measurement, all absorption peaks corresponding to the absorption peaks reported as above were detected by the above-described FT-IR measurement, thus confirming that the Si atoms and Al atoms constituting the coating film of the optical filter 11 obtained in this Example formed a chemical bond between Si atom and Al atom via an oxygen bond (Si—O—Al bond).

### Example 12

### 1. Preparation of Coating Solution

A clear and homogeneous coating solution (coating solution composition) was obtained in the same manner as in Example 1, except that 33.2 g of tetraethyl orthosilicate was used instead of 24.4 g of tetraethyl orthosilicate in “1. Preparation of coating solution” (2) of Example 1, and that 26.2 g of aluminum(III) tri-sec-butoxide was used instead of 38.5 g of aluminum(III) tri-sec-butoxide in “1. Preparation of coating solution” (3) of Example 1.

The obtained coating solution corresponds to one in which 60.0 mol % of tetraethyl orthosilicate and 40.0 mol % of aluminum(III) tri-sec-butoxide are mixed, when the total amount of tetraethyl orthosilicate and aluminum(III) tri-sec-butoxide added is regarded as 100 mol %.

Also, the solid concentration of the obtained coating solution, that is, the total content of tetraethyl orthosilicate and aluminum(III) tri-sec-butoxide, in terms of SiO₂ and Al₂O₃, respectively, in the coating solution was 5% by weight.

### 2. Formation of Coating Film

A glass substrate having protective films each formed of a monolayer structure on both main surfaces of the glass substrate formed of a phosphate glass (CM500 manufactured by HOYA Corporation, thickness 0.59 mm) (optical filter 12) was fabricated in the same manner as in Example 1, except for using the obtained coating solution as described above.

In the above-described protective films, the proportion of Al atoms in the total number of Al atoms and Si atoms is 40.0 atomic %, and the proportion of Si atoms in the total number of Al atoms and Si atoms is 60.0 atomic %.

Also, in the above-described protective films, when Al atoms and Si atoms are converted to Al₂O₃ and SiO₂, respectively, the proportion of Al₂O₃ in the total amount of Al₂O₃ and SiO₂ is 25.0 mol %, and the proportion of SiO₂ in the total amount of Al₂O₃ and SiO₂ is 75.0 mol %.

### Example 13

### 1. Preparation of Coating Solution

A clear and homogeneous coating solution (coating solution composition) was obtained in the same manner as in Example 1, except that 19.3 g of tetraethyl orthosilicate was used instead of 24.4 g of tetraethyl orthosilicate in “1. Preparation of coating solution” (2) of Example 1, and that 45.6 g of aluminum(III) tri-sec-butoxide was used instead of 38.5 g of aluminum(III) tri-sec-butoxide in “1. Preparation of coating solution” (3) of Example 1.

The obtained coating solution corresponds to one in which 33.3 mol % of tetraethyl orthosilicate and 66.7 mol % of aluminum(III) tri-sec-butoxide are mixed, when the total amount of tetraethyl orthosilicate and aluminum(III) tri-sec-butoxide added is regarded as 100 mol %.

Also, the solid concentration of the obtained coating solution, that is, the total content of tetraethyl orthosilicate and aluminum(III) tri-sec-butoxide in terms of SiO₂ and Al₂O₃, respectively, in the coating solution was 5% by weight.

### 2. Formation of Coating Film

A glass substrate having protective films each formed of a monolayer structure on both main surfaces of the glass substrate formed of a phosphate glass (CM500 manufactured by HOYA Corporation, thickness 0.59 mm) (optical filter 13) was fabricated in the same manner as in Example 1, except for using the obtained coating solution as described above.

In the above-described protective films, the proportion of Al atoms in the total number of Al atoms and Si atoms is 66.7 atomic %, and the proportion of Si atoms in the total number of Al atoms and Si atoms is 33.3 atomic %.

Also, in the above-described protective films, when Al atoms and Si atoms are converted to Al₂O₃ and SiO₂, respectively, the proportion of Al₂O₃ in the total amount of Al₂O₃ and SiO₂ is 50.0 mol %, and the proportion of SiO₂ in the total amount of Al₂O₃ and SiO₂ is 50.0 mol %.

### Comparative Example 4

### 1. Preparation of Coating Solution

A clear and homogeneous coating solution (coating solution composition) was obtained in the same manner as in Example 1, except that 52.0 g of tetraethyl orthosilicate was used instead of 24.4 g of tetraethyl orthosilicate in “1. Preparation of coating solution” (2) of Example 1, and that aluminum(III) tri-sec-butoxide was not used in “1. Preparation of coating solution” (3) of Example 1.

The obtained coating solution corresponds to one in which tetraethyl orthosilicate is 100.0 mol %.

Also, the solid concentration of the obtained coating solution, that is, the content of tetraethyl orthosilicate, in terms of SiO₂, in the coating solution was 5% by weight.

### 2. Formation of Coating Film

A glass substrate having protective films each formed of a monolayer structure on both main surfaces of the glass substrate formed of a phosphate glass (CM500 manufactured by HOYA Corporation, thickness 0.59 mm) (comparative optical filter 4) was fabricated in the same manner as in Example 1, except for using the obtained coating solution as described above.

In the above-described protective films, the proportion of Si atoms in the total number of Si atoms is 100.0 atomic %.

Also, in the above-described protective films, when Si atoms are converted to SiO₂, the proportion of SiO₂ is 100.0 mol %.

### <Confirmation of Chemical Bond (Al—O—Si Bond)>

In the same manner as in Example 10, the coating solution prepared in the above-described 1. was used to prepare a measurement sample, and FT-IR measurement on the obtained measurement sample was carried out.

As mentioned above, when FT-IR measurement is performed, absorption peaks due to Si—O—Al bonds are detected in the vicinity of 557 cm⁻¹, 850 cm⁻¹, and 902 cm⁻¹. However, for the measurement sample used in this measurement, no absorption peaks were detected in the above-described wavelength regions.

Therefore, it was confirmed that a chemical bond between Si atom and Al atom via an oxygen bond (Si—O—Al bond) was not formed in the coating film constituting the comparative optical filter 4 obtained in this Comparative Example.

### <Evaluation of Weather Resistance>

For the optical filters obtained in the above-described Examples and Comparative Examples, evaluations were conducted according to the “Weather resistance life 1” and “Weather resistance life 2” mentioned above as weather resistance evaluation methods using the haze value (degree of cloudiness).

The results for each of the Examples and Comparative Examples are shown in Table 2.

TABLE 2

| | | | Example | Example | Example | Comparative |
|---|---|---|---|---|---|---|
| | | | 11 | 12 | 13 | Example 4 |
| Whether protective film | | | Yes | Yes | Yes | Yes |
| Glass substrate | | | CM500 | CM500 | CM500 | CM500 |
| Coating | mol % in | TiO₂ | — | — | — | — |
| solution | terms of | ZrO₂ | — | — | — | — |
| | oxide | Al₂O₃ | 30.0 | 25.0 | 50.0 | — |
| | | SiO₂** | 70.0 | 75.0 | 50.0 | 100.0 |
| Protective | atomic % | Ti | — | — | — | — |
| film | | Zr | — | — | — | — |
| | | Al | 46.2 | 40.0 | 66.7 | — |
| | | Si | 53.8 | 60.0 | 33.3 | 100.0 |
| | mol % in | TiO₂ | — | — | — | — |
| | terms of | ZrO₂ | — | — | — | — |
| | oxide | Al₂O₃ | 30.0 | 25.0 | 50.0 | — |
| | | SiO₂ | 70.0 | 75.0 | 50.0 | 100.0 |

| | | | | | |
|---|---|---|---|---|---|
| Weather | Weather resistance life 1 | 750 hr | 750 hr | 1000 hr | <10 hr* |
| resistance | 65° C./90% | | | | |
| | Weather resistance life 2 | 1000 hr | 250 hr | 400 hr | <5 hr* |
| | 85° C./85% | | | | |

*In the table, “<10 hr” means less than 10 hours and “<5 hr” means less than 5 hours.

From Table 1 and Table 2, it can be seen that the optical filters obtained in Example 1 to Example 13 had, on the surface of the absorbing glass substrate formed of a phosphate glass, a weather resistant protective film having a monolayer structure, wherein the weather resistant protective film contained one or more selected from Ti atoms, Zr atoms, and Al atoms together with Si atoms, and the proportion of the total number of atoms of Ti atoms, Zr atoms, and Al atoms in the total number of Si atoms, Ti atoms, Zr atoms, and Al atoms was more than 20.0 atomic % and 75.0 atomic % or less, and it can be also seen that they thus had sufficiently long weather resistance lives (weather resistance life 1 and weather resistance life 2), which are specified by the limit time for a haze value of 0.2 or less, of 200 hr (200 hours) to 1000 hr (1000 hours) and also maintained the surface in a homogeneous and transparent state during the weather resistance lives as observed visually, exhibiting excellent weather resistance.

Also, from the results of Example 11, etc., it was considered that the optical filters obtained in the above-described respective Examples had a specific structure in which Si atoms and one or more selected from Ti atoms, Zr atoms, and Al atoms, which constituted the weather resistant protective film, were bonded in the form of a three dimensional network by a chemical bond via an oxygen atom between homologous atoms or between heterologous atoms, and thus exhibited excellent weather resistance.

On the other hand, it can be seen from Table 1 that, since the optical filter obtained in Comparative Example 1 had no protective film on the surface of the absorbing glass substrate formed of a phosphate glass, the haze value exceeded 0.2 after 10 hours or 5 hours of exposure in the thermo-hygrostat chamber, and at that time, it was also found by the visual observation that the surface became deliquescent and sticky, resulting in deterioration. Thus it can be seen that the optical filter obtained in Comparative Example 1 had poor weather resistance.

Also, it can be seen from Table 1 that, since the optical filter obtained in Comparative Example 2 had, on the surface of the absorbing glass substrate formed of a phosphate glass, a weather resistant protective film in which the proportion of the number of atoms of Ti atoms in the total number of Si atoms and Ti atoms was outside the predetermined range, the weather resistance lives, which was specified by the limit time for maintaining a haze value of 0.2 or less, were as short as 50 hr (50 hours) or 10 hr (10 hours). Thus, it can be seen that the optical filter obtained in Comparative Example 2 had poor weather resistance.

In addition, it can be seen from Table 1 that, since the optical filter obtained in Comparative Example 3 had, on the surface of the absorbing glass substrate formed of a phosphate glass, a weather resistant protective film in which the proportion of the number of atoms of Ti atoms in the total number of Si atoms and Ti atoms was outside the predetermined range, the weather resistance lives, which was specified by the limit time for maintaining a haze value of 0.2 or less, were as short as 150 hr (150 hours) or 40 hr (40 hours). Thus, it can be seen that the optical filter obtained in Comparative Example 3 had indicates poor weather resistance.

From the results of Comparative Example 4, it was considered that the optical filters obtained in the above-described respective Comparative Examples were inferior in weather resistance since they did not include, as a weather resistant protective film, one having a specific structure in which Si atoms and one or more selected from Ti atoms, Zr atoms, and Al atoms are bonded in the form of a three dimensional network by a chemical bond via an oxygen atom between homologous atoms or between heterologous atoms.

### REFERENCE SIGNS LIST

1 optical element, optical filter, or infrared cut filter (IRCF)
L lens
CG cover glass
IC image sensor
G glass substrate
P weather resistant protective film
AR antireflection film
R resin film

1. An optical element comprising: a glass substrate formed of a phosphate glass or a fluorophosphate glass; and a weather resistant protective film provided on at least one main surface of the glass substrate and having a monolayer structure,
wherein the weather resistant protective film contains one or more selected from Ti atoms, Zr atoms, and Al atoms together with Si atoms, and
a proportion of the total number of Ti atoms, Zr atoms, and Al atoms in the total number of Si atoms, Ti atoms, Zr atoms, and Al atoms is more than 20.0 atomic % and 75.0 atomic % or less.

2. The optical element according to claim 1, wherein Si atoms and one or more selected from Ti atoms, Zr atoms, and Al atoms, which constitute the weather resistant protective film, are bonded in a form of a three dimensional network by a chemical bond via an oxygen atom between homologous atoms or between heterologous atoms.

3. The optical element according to claim 1, wherein the weather resistant protective film contains 8.3 to 27.5 atomic % of Si atoms, 6.6 to 28.5 atomic % of one or more selected from Ti atoms, Zr atoms, and Al atoms, and 61.9 to 66.6 atomic % of oxygen atoms.

4. The optical element according to claim 1, wherein the weather resistant protective film contains a reaction product of
(I) one or more silicon compounds selected from alkoxysilanes, alkoxysilane derivatives, or oligomers as polymerization products of one or more thereof, with one or more multivalent metal compounds selected from
(IIa) alkoxytitaniums, alkoxytitanium derivatives, or oligomers as polymerization products of one or more thereof,
(IIb) alkoxyzirconiums, alkoxyzirconium derivatives, or oligomers as polymerization products of one or more thereof, and
(IIc) alkoxyaluminums, alkoxyaluminum derivatives, or oligomers as polymerization products of one or more thereof.

5. The optical element according to claim 1, comprising: the glass substrate formed of a phosphate glass or a fluorophosphate glass; and the weather resistant protective film provided on at least one main surface of the glass substrate, wherein the weather resistant protective film contains a hydrolysis and dehydration condensation product of
an alkoxysilane represented by the following general formula (i): 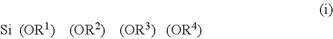
wherein R¹, R², R³, and R⁴ are linear or branched hydrocarbon groups having 1 to 10 carbon atoms, which may be identical or different from each other, with one or more selected from metal alkoxides each represented by
the following general formula (iia): 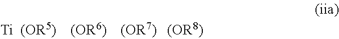
wherein R⁵, R⁶, R⁷, and R⁸ are linear or branched hydrocarbon groups having 1 to 10 carbon atoms, which may be identical or different from each other,
the following general formula (iib): 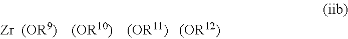
wherein R⁹, R¹⁰, R¹¹, and R¹² are linear or branched hydrocarbon groups having 1 to 10 carbon atoms, which may be identical or different from each other, and
the following general formula (iic): 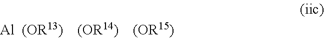
wherein R¹³, R¹⁴, and R¹⁵ are linear or branched hydrocarbon groups having 1 to 10 carbon atoms, which may be identical or different from each other.

6. The optical element according to claim 5, wherein, when a total content of the alkoxysilane represented by the general formula (i) and the one or more metal alkoxides selected from the general formula (iia) to the general formula (iic) is regarded as 100.0 mol %, the weather resistant protective film contains a hydrolysis and dehydration condensation product of
25.0 mol % or more and less than 80.0 mol % of the alkoxysilane represented by the general formula (i) with more than 20.0 mol % and 75.0 mol % or less of the one or more metal alkoxides selected from the general formula (iia) to the general formula (iic).

7. The optical element according to claim 1, wherein the glass substrate is an absorbing glass substrate that absorbs ultraviolet light or near infrared light.

8. The optical element according to claim 1, further comprising a resin film or an antireflection film on the weather resistant protective film.

9. The optical element according to claim 1, further comprising a resin film and an antireflection film in this order, or further comprising an antireflection film and a resin film in this order, on the weather resistant protective film.

10. The optical element according to claim 1, wherein the optical element is an optical filter.

11. An imaging device comprising the optical element according to claim 1 as an optical filter, together with a solid state imaging element and an imaging lens.
